(19) United States
(12) Patent Application Publication
(10) Pub. No.: US 2026/0146359 A1
(43) Pub. Date: May 28, 2026

(54) IN SITU DEFECT MITIGATION IN CRYSTAL GROWTH

(71) Applicant: Wolfspeed, Inc., Durham, NC (US)

(72) Inventors: Valeri Fedorovich Tsvetkov, Durham, NC (US); Caleb Andrew Kent, Durham, NC (US); Brian Bennett Haidet, Raleigh, NC (US); Benjamin Lefler Layne, Durham, NC (US)

(21) Appl. No.: 19/341,950

(22) Filed: Sep. 26, 2025

Related U.S. Application Data
(63) Continuation-in-part of application No. 19/239,693, filed on Jun. 16, 2025.
Application No. 19/239,693 is a continuation-in-part of application No. 18/962,454, filed on Nov. 27, 2024.
(60) Provisional application No. 63/779,889, filed on Mar. 28, 2025.

(51) Int. Cl. C30B 23/00; C30B 23/02; C30B 23/06; C30B 29/36

(52) U.S. Cl. CPC C30B 23/002; C30B 23/025; C30B 23/066; C30B 29/36

(57) ABSTRACT

Systems and methods for defect mitigation in silicon carbide crystal growth systems are provided. In an aspect, an example method includes providing a crystalline material in a first zone of the crystal growth chamber. In some implementations, the example method includes providing a silicon carbide vapor source material in a second zone of the crystal growth chamber. The example method includes providing an etching agent in the crystal growth chamber. The example method includes controlling a temperature gradient in the crystal growth chamber such that a first temperature in the first zone is greater than a second temperature in the second zone to implement an etching process on the crystalline material in the crystal growth chamber.

### PRIORITY CLAIM

The present application is a continuation-in-part of and claims priority to U.S. patent application Ser. No. 19/239,693, filed on Jun. 16, 2025, which is hereby incorporated by reference, which is a continuation-in-part of and claims priority to U.S. patent application Ser. No. 18/962,454, filed on Nov. 27, 2024, which is hereby incorporated by reference. The present application claims the benefit of and priority to U.S. Provisional Patent Application Ser. No. 63/779,889, filed on Mar. 28, 2025, which is incorporated by reference.

### FIELD

The present disclosure relates generally to crystal growth systems, such as silicon carbide crystal growth systems for growing crystalline silicon carbide workpieces.

### BACKGROUND

Semiconductor devices, including power semiconductor devices based on wide bandgap materials, may be formed on a semiconductor wafer as part of a semiconductor fabrication process. Single crystal silicon carbide has proven to be a very useful wafer material in the manufacture of such semiconductor devices. Due to its physical strength and excellent resistance to many chemicals, silicon carbide may be used to fabricate very robust substrates adapted for use in the semiconductor industry. Silicon carbide has excellent electrical properties, including radiation hardness, high breakdown field, a relatively wide bandgap, high saturated electron drift velocity, high-temperature operation, and absorption and emission of high-energy photons in the blue, violet, and ultraviolet regions of the optical spectrum.

### SUMMARY

Aspects and advantages of embodiments of the present disclosure will be set forth in part in the following description, or can be learned from the description, or can be learned through practice of the embodiments.

In an aspect, the present disclosure provides an example method. In some implementations, the example method includes providing a crystalline material in a first zone of the crystal growth chamber. In some implementations, the example method includes providing a silicon carbide vapor source material in a second zone of the crystal growth chamber. In some implementations, the example method includes providing an etching agent in the crystal growth chamber. In some implementations, the example method includes controlling a temperature gradient in the crystal growth chamber such that a first temperature in the first zone is greater than a second temperature in the second zone to implement an etching process on the crystalline material in the crystal growth chamber.

In an aspect, the present disclosure provides an example method. In some implementations, the example method includes providing a crystalline material in a first zone of the crystal growth chamber. In some implementations, the example method includes providing a silicon carbide vapor source material in a second zone of the crystal growth chamber, the second zone separated from the first zone by an interface structure. In some implementations, the example method includes controlling a temperature gradient in the crystal growth chamber such that a first temperature in the first zone is greater than a second temperature in the second zone to implement an etching process on the crystalline material in the crystal growth chamber.

In an aspect, the present disclosure provides an example method. In some implementations, the example method includes providing a source material in the crystal growth chamber, the source material including a silicon carbide vapor source material and a metal-containing additive. In some implementations, the example method includes heating the source material such that the metal-containing additive vaporizes and reacts with impurities on a surface of the silicon carbide vapor source material.

In an aspect, the present disclosure provides an example method. In some implementations, the example method includes providing a crystalline material and a source material in the crystal growth chamber. In some implementations, the example method includes providing a carbon getter material in the crystal growth chamber at a location between the crystalline material and the source material. In some implementations, the example method includes heating the crystal growth chamber to a temperature sufficient to cause the carbon getter material to consume elemental carbon from an environment of the chamber, thereby creating a silicon-rich vapor that etches a surface of the crystalline material.

In an aspect, the present disclosure provides an example method. In some implementations, the example method includes applying a sacrificial coating to a surface of the seed crystal. In some implementations, the example method includes placing the seed crystal with the sacrificial coating into a crystal growth chamber. In some implementations, the example method includes heating the crystal growth chamber to cause the sacrificial coating to etch a surface layer of the seed crystal.

In an aspect, the present disclosure provides an example crystal growth system. In some implementations, the example crystal growth system includes a crystal growth chamber including a first zone and a second zone. In some implementations, the example crystal growth system includes a crystalline material in the first zone. In some implementations, the example crystal growth system includes an etching agent in the crystal growth chamber. In some implementations, the example crystal growth system includes a controller configured to control a temperature gradient between the first zone and the second zone such that a first temperature of the first zone is greater than a second temperature of the second zone to implement an etching process on the crystalline material.

In an aspect, the present disclosure provides an example crystal growth system. In some implementations, the example crystal growth system includes a crystal growth chamber including a first zone and a second zone. In some implementations, the example crystal growth system includes a crystalline material in the first zone. In some implementations, the example crystal growth system includes a silicon carbide vapor source material in the second zone. In some implementations, the example crystal growth system includes an etching agent holder separated from the silicon carbide vapor source material operable to hold an etching agent material in the crystal growth chamber.

In an aspect, the present disclosure provides an example crystal growth system. In some implementations, the example crystal growth system includes a crystal growth chamber including a first zone and a second zone. In some implementations, the example crystal growth system includes a crystalline material in the first zone. In some implementations, the example crystal growth system includes a silicon carbide vapor source material in the second zone. In some implementations, the silicon carbide vapor source includes a composite material, wherein the composite material includes an etching agent for etching the crystalline material in the crystal growth chamber.

In an aspect, the present disclosure provides a crystal growth system. The crystal growth system includes a crystal growth chamber; a seed crystal in a first zone of the crystal growth chamber; a source material in a second zone of the growth chamber; and a carbon getter material positioned between the source material and the seed crystal.

In an aspect, the present disclosure provides an example method. In some implementations, the example method includes providing a crystalline material and a source material within a semi-permeable crystal growth chamber. In some implementations, the example method includes establishing a forward temperature gradient in the crystal growth chamber such that the source material is at a higher temperature than the crystalline material, defining a source flux of vapor from the source material to the crystalline material. In some implementations, the example method includes introducing an inert gas into the crystal growth chamber at a pressure sufficient to impede the source flux, such that an outward leak flux of material from the crystalline material through the semi-permeable crystal growth chamber is greater than the source flux, thereby causing a net removal of material from a surface of the crystalline material.

Variations and modifications can be made to these embodiments of the present disclosure.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussions of embodiments directed to one of ordinary skill in the art are set forth in the specification, which makes reference to the appended figures, in which:

FIG. 1 is a cross-sectional schematic diagram of a crystal growth system adapted for use in a crystal growth process.

FIG. 2 is a cross-sectional schematic diagram of a crystal growth system with independent control over a plurality of zones according to example embodiments of the present disclosure.

FIG. 3 depicts the crystal growth system during an in-situ etching process under an inverted temperature gradient condition according to example embodiments of the present disclosure.

FIG. 4 depicts the crystal growth system during a bulk crystal growth process under a forward temperature gradient condition according to example embodiments of the present disclosure.

FIG. 5 depicts the crystal growth system during an in-situ etching process on a bulk crystalline material according to example embodiments of the present disclosure.

FIG. 6 is a schematic illustrating a crystalline material before and after an in-situ etching process.

FIG. 7 depicts an example embodiment of the crystal growth system where an etching agent is provided in a dedicated holder.

FIG. 8 depicts an example embodiment of the crystal growth system where an etching agent is provided at an interface structure between zones.

FIG. 9 depicts an example embodiment of the crystal growth system where an etching agent is integrated with the source material to form a composite source.

FIG. 10 depicts an example embodiment of the crystal growth system where an etching agent is introduced as a gas via a gas inlet.

FIG. 11 depicts an example embodiment of the crystal growth system where an etching agent is layered within the source material for periodic etching.

FIG. 12 depicts an example embodiment of a crystal growth system configured to perform an in-situ seed etching process using a carbon getter material as the etching agent according to example embodiments of the present disclosure.

FIG. 13 depicts a schematic illustrating a seed preparation process using a sacrificial coating according to example embodiments of the present disclosure.

FIG. 14 depicts a graph showing the thermodynamic relationships between silicon vapor pressures for an in-situ etching process according to examples of the present disclosure.

FIG. 15 is a flowchart illustrating an example method according to examples of the present disclosure.

FIG. 16 is a flowchart illustrating an example method according to examples of the present disclosure.

FIG. 17 is a flowchart illustrating an example method according to examples of the present disclosure.

FIG. 18 is a flowchart illustrating an example method according to examples of the present disclosure.

FIG. 19 depicts a crystal growth system according to example embodiments of the present disclosure.

FIG. 20 depicts a crystal growth system according to example embodiments of the present disclosure.

FIG. 21 depicts a crystal growth system according to example embodiments of the present disclosure.

FIG. 22 depicts a crystal growth system according to example embodiments of the present disclosure.

FIG. 23 depicts a crystal growth system according to example embodiments of the present disclosure.

FIG. 24 depicts a crystal growth system according to example embodiments of the present disclosure.

FIG. 25 depicts a crystal growth system according to example embodiments of the present disclosure.

Repeat use of reference characters in the present specification and drawings is intended to represent the same and/or analogous features or elements of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Examples of the present disclosure describe methods and systems for growing high-quality silicon carbide crystalline material using a physical vapor transport (PVT) process. This technology addresses the problem of defects forming in the crystalline material. For instance, the technology addresses the problem of defects forming at the interface between the seed crystal and the bulk crystal grown on the seed crystal, which compromises the quality and yield of the final product.

Growing a crystal on a seed with subsurface damage, scratches, or surface contamination may lead to defects that propagate throughout the grown bulk crystalline material. While reversing the temperature gradient to etch the seed surface in situ has been attempted, this approach may cause graphitization (the formation of an undesirable carbon layer) on the seed, introducing new defects.

Furthermore, while the quality of the seed crystal may be important, defects can also be introduced from a silicon carbide vapor source material itself. In a PVT process, impurities on the surface of the silicon carbide source material grains can evaporate or sublimate during the initial system heat-up. These impurities, particularly oxygen-related compounds, can then be transported to the colder seed crystal, poisoning the growth surface and creating a defective interface where the new crystal begins to grow. Such “start-of-growth” (SOG) defects can compromise the quality of the bulk crystalline material grown on the seed crystal.

Aspects of the present disclosure introduce an improved in situ etching process that cleans the crystalline surface with reduced graphitization and/or reduces defects that can propagate through the crystal. The process involves placing a seed crystal in a first zone of a crystal growth chamber and a silicon carbide vapor source in a second zone. An etching agent is also provided in the growth chamber. To initiate the etching process, a controller establishes an inverted temperature gradient in the growth chamber, making the seed crystal in the first zone hotter than the silicon carbide vapor source in the second zone.

This inverted temperature gradient causes the crystalline material—either the initial seed crystal or the bulk crystal during a pause in growth—to be etched, thereby removing the damaged or contaminated surface layers. The addition of the etching agent may enhance etching of the crystalline material during the inverted temperature gradient and/or may reduce graphitization during this high-temperature etching. The etching agent can be a silicon vapor (e.g., from an elemental silicon powder, Si₃N₄, or other silicon vapor source), a gas (such as nitrogen, hydrogen, carbon monoxide, hydrocarbon (e.g., methane), a sulfur-containing gas, silicon-containing gas (e.g., silane)), or a metal vapor, such as a vapor of an elemental metal or metal compound, (e.g., from a metal vapor source such as a rare earth metal such as lanthanum, cerium, praseodymium, or neodymium). The etching agent can be supplied from a dedicated holder or integrated directly into the source material as a composite structure (e.g., silicon and silicon carbide composite structure).

More particularly, in some examples, an in situ process to remove the subsurface damage and contamination from a crystalline material is achieved by introducing elemental silicon into the silicon carbide vapor source and employing an inverted temperature gradient during the initial crucible heat-up phase and/or during bulk crystal growth. In this configuration, the seed crystal's temperature (T1) is intentionally maintained at a higher level than the source material's temperature (T2). This setup induces a controlled etching of the surface of the crystalline material (e.g., the seed crystal or bulk crystalline material grown on the seed crystal), removing the compromised layers and leaving a pristine surface for subsequent crystal growth.

In particular aspects, surface graphitization of the crystalline material is reduced during the etching process. In a typical carbon-rich environment, heating silicon carbide can cause it to decompose, leaving a layer of solid carbon (graphite) via the reaction:

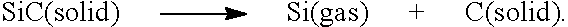

The introduction of elemental silicon as an etching agent into the crystal growth chamber (e.g., at the silicon carbide vapor source material) counteracts this tendency by increasing the silicon vapor pressure within the growth chamber. In some cases, for the etching to proceed with reduced graphitization, the silicon vapor pressure generated by the elemental silicon source can be higher than the equilibrium silicon vapor pressure over the crystalline material surface (e.g., the seed surface) at temperature T1. This condition suppresses the graphitization reaction and instead promotes the sublimation of the seed via an alternative pathway:

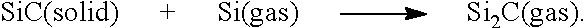

In some aspects, the rate of the etch is a function of the seed temperature (T1) and/or the magnitude of the temperature difference between the seed and the source (T1−T2). The placement of the elemental silicon can be varied, such as being interspersed in layers within the source material or placed on interface structures, to control the timing of the etch-back process. Furthermore, while elemental silicon is the primary etching agent discussed, the scope of the method could include other etching agents. Alternative gaseous agents such as nitrogen, hydrogen, carbon monoxide, hydrocarbons (e.g., methane), sulfur-containing gases and/or silicon-containing gases (e.g., silane) may be used.

In some embodiments, metal vapors can be employed for in-situ etching or cleaning or to otherwise mitigate defects during crystal growth. For in-situ etching of the crystalline material, a metal vapor source including one or more rare earth metals—such as lanthanum, cerium, praseodymium, or neodymium—may be located within the growth chamber. During an etching process, the rare earth metal vapor can be transported to and be deposited on the surface of the crystalline material to etch it.

For in-situ impurity removal, a metal vapor from a source including alkali earth metals (e.g., calcium, strontium, or barium) and/or post-transition metals (e.g., tin, bismuth, or lead) can be used. These metals may act, for instance, as agents to remove impurities, such as oxygen-based impurities, from the surface of the crystalline material and/or the source material as described below. In some embodiments, the metal vapor may be used to etch and/or remove impurities under an inverted temperature gradient condition. However, in some embodiments, the metal vapor may be used to etch and/or remove impurities without requiring an inverted temperature gradient condition (e.g., by using a forward temperature gradient).

For certain applications where unintended doping is to be avoided, such as the fabrication of power devices, the chosen metal may be a non-incorporating agent. For etching applications, the aforementioned rare earth metals are non-incorporating etchants that etch the silicon carbide surface but do not readily incorporate into the crystal lattice or alter its electrical properties. Similarly, for impurity gettering applications, the alkali earth and post-transition metals are suitable non-incorporating agents due to their low solubility and reactivity in silicon carbide. In some embodiments, the quantity of the etching agent, concentration of the etching agent, process recipe, temperature, and/or other parameters can be selected and/or adjusted to reduce incorporation of the agent (e.g., metal inclusions) in the crystal lattice.

In some embodiments, the present disclosure describes a method for in-situ cleaning and conditioning of the silicon carbide source material using a source conditioning agent, which can include alkali earth metals (e.g., calcium, strontium, or barium), post-transition metals (e.g., tin, bismuth, or lead) and/or rare earth metals (e.g., lanthanum, cerium, praseodymium, or neodymium). The method can include intermixing an additive comprising a metal or metal compound with the source material. During the initial heat-up phase, for instance at a temperature between about 500° C. and 2000° C., such as about 700° C. to about 1900° C., such as about 1200° C. to about 1900° C., such as about 1400° C. to about 1900° C., the additive vaporizes to improve growth conditions and/or mitigate defects.

Without being bound by any particular theory of operation, the functions of this source conditioning agent may include modifying the surface of the source material grains. For instance, the surface modification may include removing oxide layers and producing a light graphitization. This surface modification may reduce the tendency for individual silicon carbide grains to sinter together during the process. In some examples, the vaporized additive reacts with and removes impurities from the surface of the source material, preventing them from contaminating the seed crystal and reducing the formation of SOG defects.

The metal-containing additive can be supplied in various forms, including a pure metal, an oxide, a silicate, a carbide, or another suitable metal compound. When the additive is a metal oxide, it may be combined with an oxygen-getter, such as elemental carbon or silicon, to mitigate the effects of oxygen release during the heat-up phase.

The selection of specific metals can be tailored to achieve desired effects. As noted, alkali earth and post-transition metals are particularly useful due to their low solubility and reactivity in silicon carbide, which reduces the risk of unintentional doping. These metals may also exhibit low adhesion to the crystal surface, and any incidental deposits can be removed with an in-situ etch-back process. Furthermore, in addition to conditioning the source material, the vaporized additive from these metals may provide the secondary benefit of reacting with and removing impurities, such as oxygen, from the surface of the seed or growing crystal itself.

In some embodiments, a clean etching of the seed crystal surface may be achieved in-situ without an inverted temperature gradient (e.g., where T₁>T₂). For instance, in some embodiments, a “carbon getter” material may be placed within the crystal growth chamber 104 to chemically alter the vapor environment and induce a non-graphitizing in-situ etch. In this method, the etching agent comprises a carbon getter material (e.g., tantalum oxide (Ta₂O₅) or other suitable oxides, nitrides, or elements known to have a high chemical affinity for carbon) is positioned in the crucible between the silicon carbide vapor source material and the seed crystal. For instance, the tantalum oxide could be placed on or integrated with an interface structure. During the heat-up phase, the tantalum oxide acts as a chemical sink for elemental carbon present in the chamber environment and/or increasing the silicon:carbon ratio of SixCy species.

One mole of tantalum oxide can consume seven moles of elemental carbon via the reaction:

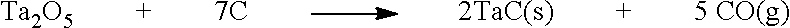

Another example of silicon enriching a silicon carbide gas is provided below:

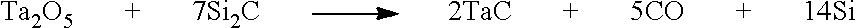

By consuming carbon from the environment, the etching agent comprising the carbon getter creates a silicon-rich atmosphere in the vicinity of the seed crystal. This silicon-rich condition shifts the thermodynamic equilibrium at the seed surface, favoring the removal of SiC and suppressing the formation of a graphitic layer. The result is a clean, non-graphitizing etch of the seed crystal surface that removes subsurface damage and contamination, even while the system maintains a standard or forward temperature gradient for growth. This process may continue until the getter material is fully converted to tantalum carbide.

In some embodiments, an etchback of the crystalline material can be achieved with an etching agent under a forward temperature gradient (T₁<T₂). This method is particularly applicable in crystal growth systems that utilize semi-permeable crucibles, such as those with inherent porosity or leaks. During the process, the flux of vapor from the source material to the seed is controlled by the thermal gradient, but a simultaneous outward “leak flux” also exists, where material from the seed disperses away from the growth surface and out of the crucible. By introducing a sufficiently high pressure of an inert gas, the transport of silicon-containing species to the seed is impeded, reducing the source flux. If the inert gas pressure is controlled such that the leak flux is greater than the source flux, a net removal of material from the seed surface occurs, resulting in an etch. The etch products are then dispersed away from the seed through the leaks or pores in the crucible, providing a method to control surface etching by manipulating gas pressure rather than reversing the thermal gradient.

Another aspect of the disclosure is directed to preparing the seed crystal surface by applying a sacrificial, evaporable coating before the seed is loaded into the crystal growth chamber. This method involves creating a protective layer on the seed crystal surface that may serve a dual purpose. First, the formation or application of the coating treats and consumes the top layer of the seed crystal, removing pre-existing subsurface damage. Second, the coating itself protects the newly prepared surface and then evaporates away entirely during the initial crucible heat-up, taking any defects and impurities with it and leaving a pristine surface for growth.

For instance, in some embodiments, the seed crystal is prepared by thermal oxidation. The silicon carbide seed is heated in an oxygen-containing atmosphere, which consumes the top layer of SiC to form a protective layer of silicon oxide (SiOₓ). This reaction can be described as:

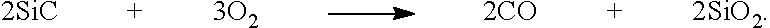

During the subsequent heat-up inside the crystal growth chamber, this SiO_{X} layer (e.g., SiO₂) has a much higher vapor pressure than the underlying SiC and freely evaporates, exposing a pristine surface to the crucible interior just before growth begins.

In some embodiments, a silicon-oxide (SiOx) layer can be applied to the surface of the seed using a room-temperature wet chemistry process. For example, a compound such as tetraethyl orthosilicate (TEOS) can be used to deposit the SiOx coating. Similar to the thermally grown oxide, this chemically applied layer etches the seed surface and then evaporates during heat-up to prepare the surface for growth.

In another embodiment, the sacrificial coating is a layer of elemental silicon or metal capable of dissolving silicon carbide deposited directly onto the seed crystal. This deposition can be accomplished by applying silicon powder, which is then melt-adhered. In some embodiments, the deposition is accomplished through techniques such as e-beam evaporation or sputtering. During crucible heat-up, the elemental silicon melts and dissolves the top layer of the silicon carbide seed, performing a solid-liquid etchback. As the excess silicon evaporates, the dissolved silicon carbide is redeposited, leaving behind a clean surface for subsequent bulk crystal growth.

Examples of the present disclosure are directed to methods and systems for growing silicon carbide crystalline material using a PVT process that incorporates one or more in-situ etching techniques. In some embodiments, a seed crystal is provided in a first zone of a crystal growth chamber and a silicon carbide vapor source material is provided in a second zone. An etching agent is also provided in the chamber to facilitate a controlled etching process on a crystalline material, such as the seed crystal or a subsequently grown bulk crystal, to remove defects and prepare a pristine surface for high-quality growth.

In some embodiments, a method for etching may include the manipulation of temperature in a crystal growth system. A controller can be configured to manage a temperature gradient between the two zones, for example by controlling separate heaters for each zone. To implement an etching process, the temperature gradient is controlled such that a first temperature in the first zone is greater than a second temperature in the second zone (a “inverted” temperature gradient). After etching the seed crystal or a bulk crystalline material, the controller can invert or reverse the gradient, making the first temperature less than the second, to implement or resume a bulk crystal growth process. An interface structure may be positioned between the zones to assist in controlling the thermal and vapor transport environments. The etch rate can be controlled by adjusting the temperature difference, which may be in a range of about 30° C. to 100° C., to remove a desired amount of material, such as about 10 to about 100 microns, such as about 10 microns to about 75 microns, such as about 25 microns to about 50 microns.

In some embodiments, to facilitate a clean etching process and reduce the formation of undesirable graphitic carbon, a silicon-based etching agent can be used. This involves generating a silicon vapor from a silicon vapor source to create a silicon-rich atmosphere. The silicon vapor source may comprise solid silicon, silicon powder, or a compound like Si₃N₄. The source can be provided in a dedicated holder separated from the main silicon carbide source material, or it can be integrated with the silicon carbide source to form a composite structure, ensuring that the silicon vapor pressure at the source is greater than the equilibrium silicon vapor pressure at the hotter seed crystal surface.

In some embodiments, the etching agent can be introduced into the chamber as a gas. The gas may include one or more of nitrogen, hydrogen, carbon monoxide, a hydrocarbon, a sulfur-containing gas, or a silicon-containing gas. This gas can be used to alter the equilibrium Si:C ratio in the vapor to control the nature of the etchback. In some applications, the gas is injected directly into the interior of the reaction crucible to prevent pre-reaction with hot graphite fixtures. The gas etching may also be performed as a multi-step process, wherein the seed surface is first thermally graphitized and then the newly formed graphitic surface is chemically etched away by the gas.

The etching agent may also be a metal vapor. A metal vapor source, comprising one or more of a rare earth metal such as lanthanum, cerium, praseodymium, or neodymium, can be provided in the chamber. In some embodiments, during the etching process, the metal vapor deposits on the surface of the crystalline material. This deposited metal preferentially attacks and removes defective regions such as dislocations, stacking faults, and micropipes. For applications such as power devices, a non-incorporating etchant is used so that the metal does not alter an electrical property of the final crystal.

In some embodiments, the etching can be achieved without an inverted temperature gradient, for instance, by using a carbon getter. A carbon getter material, such as tantalum oxide, can be placed in the chamber between the source and the seed, for example on an interface structure. During heat-up, this material consumes elemental carbon from the environment, which in turn creates a silicon-rich atmosphere that chemically etches the seed surface even under a forward or neutral temperature gradient.

In some embodiments, an etchback of the crystalline material can be achieved under a forward temperature gradient (T₁<T₂), which is typically a condition for growth. This method is particularly applicable in crystal growth systems that utilize semi-permeable crucibles, such as those with inherent porosity or leaks. During the process, the flux of vapor from the source material to the seed is controlled by the thermal gradient, but a simultaneous outward “leak flux” also exists, where material from the seed disperses away from the growth surface and out of the crucible. By introducing a sufficiently high pressure of an inert gas, the transport of silicon-containing species to the seed is impeded, reducing the source flux. If the inert gas pressure is controlled such that the leak flux is greater than the source flux, a net removal of material from the seed surface occurs, resulting in an etch. The etch products are then dispersed away from the seed through the leaks or pores in the crucible, providing a method to control surface etching by manipulating gas pressure rather than reversing the thermal gradient. As used herein, a semi-permeable crystal growth chamber is a chamber or a reaction crucible having walls characterized by inherent porosity or leaks that permit an outward flux of material from its interior environment.

In some implementations, the method of controlling the etch rate via inert gas pressure can be combined with the introduction of a chemical etching agent. Examples of such an etching agent include, but are not limited to, a silicon vapor from a silicon vapor source, a reactive gas such as nitrogen, hydrogen, a hydrocarbon, or a silicon-containing gas, or a metal vapor from a metal source (e.g., rare earth metal source). This combination may provide a synergistic effect where the etching agent enhances the removal of specific impurities or preferentially attacks defective regions on the crystalline surface, while the pressure-controlled flux ensures the efficient transport of the resulting etch products away from the surface.

In some embodiments, the seed crystal is prepared by applying a sacrificial, evaporable coating to its surface prior to being loaded into the crucible. This coating first etches a surface layer of the seed and subsequently evaporates during heat-up, exposing a surface with reduced defects. The sacrificial coating can be a silicon oxide (SiOx) layer, formed either by thermally oxidizing the seed or by applying it via a wet chemistry process using a precursor like TEOS. Alternatively, the coating can be a layer of elemental silicon, which melts during heat-up to perform a solid-liquid etchback on the seed surface before evaporating.

Aspects of the present disclosure provide numerous technical effects and benefits. A primary technical problem solved is the preparation of a defect-reduced seed crystal surface for PVT growth of silicon carbide crystalline material. Heating of a seed crystal to clean it may leave a detrimental graphitic layer that introduces crystallographic defects during growth. Furthermore, the seed crystal may contain subsurface damage from mechanical preparation, and these defects act as a template that propagates throughout the entire bulk crystal, degrading its quality and rendering it unusable for high-performance electronic applications.

The technical solution according to aspects of the present disclosure involves an in-situ etching process that physically removes the damaged and contaminated surface layer of the seed crystal before growth begins or before further growth of bulk crystalline material. In some aspects, this can be achieved by establishing an inverted temperature gradient, making the seed hotter than the silicon carbide vapor source material. This may be performed in a controlled atmosphere created by an etching agent, such as a silicon vapor, a reactive gas, or a metal vapor. This etching agent may alter the thermodynamic conditions at the seed surface, reducing graphitization. This allows for the clean removal of crystalline material, reducing the subsurface damage and leaving a pristine, silicon carbide crystalline material surface ready for growth. Furthermore, in some examples, the source conditioning method can be advantageously used in combination with any of the disclosed in-situ etching techniques (e.g., inverted gradient, carbon getter) to provide a multi-pronged approach to defect reduction: cleaning the source material before it can release impurities and cleaning the crystal surface to remove any defects that form during growth. This allows for the clean removal of crystalline material, reducing the subsurface damage and leaving a silicon carbide crystalline material surface ready for growth.

The technical effect is an improvement in the quality and yield of the final silicon carbide crystalline material boule. By starting growth on a crystallographically improved surface, the propagation of defects from the seed is reduced. Beyond initial preparation, this process can be applied intermittently during bulk growth. The system allows for pausing the growth, reversing the temperature gradient to etch away any newly formed defective layers caused by process fluctuations, and then resuming growth on the refreshed surface. This ability to perform mid-growth correction reduces transient issues from compromising the entire crystal growth run and can lead to a final product with a much lower defect density.

It is to be understood, using the disclosures provided herein, that the disclosed defect mitigation and etch-back processes according to examples of the present disclosure can be implemented with flexibility throughout the entire crystal growth process. In some embodiments, the etching process is performed as a single operation at the beginning of the growth process to prepare the surface of the seed crystal. In some embodiments, the process can be applied intermittently during the bulk growth phase. These subsequent etching operations may be implemented as part of a predetermined recipe, occurring at regular or irregular intervals designed to correct for known process fluctuations. Moreover, the initiation of an etch-back cycle can be implemented dynamically in response to real-time conditions. For example, a controller can be configured to trigger an etching process “on the fly” based on feedback from sensors monitoring the growth environment, which may indicate an increased likelihood of defect formation. In some embodiments, the timing and parameters of the etching process may be determined by a machine learning model. This model can be trained on data from previous growth runs to predict the onset of defect formation and proactively initiate a corrective etch cycle. This can provide for a dynamic and adaptive growth recipe that can be modified based on prior process outcomes and/or real-time sensor feedback, providing a highly optimized and self-correcting crystal growth process.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “central portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel. “Non-perpendicular” means not perpendicular.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the disclosure. The thickness of layers and regions in the drawings may be exaggerated for clarity. Additionally, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the disclosure are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

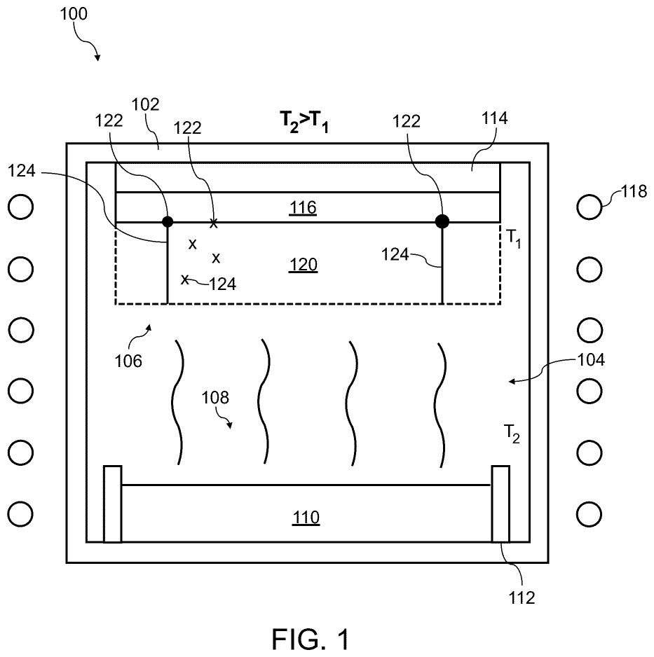

FIG. 1 is a cross-sectional schematic diagram of a crystal growth system 100 adapted for use in a crystal growth process. The crystal growth system 100 can include a reaction crucible 102 that defines a crystal growth chamber 104 that can be divided into a first zone 106 and a second zone 108. The second zone 108 can contain a silicon carbide vapor source material 110 supported by a source material holder 112, from which a sublimation of vapor occurs. The first zone 106 can contain a seed crystal 116 supported by a seed holder 114. The seed crystal 116 can have a surface of crystalline material and may contain defects 122. The crystal growth system 100 can also include a heater 118 to create temperature gradients between the first zone 106 and the second zone 108 in the crystal growth chamber 104.

The crystal growth system 100 may be configured to implement a PVT process. More particularly, the crystal growth system 100 includes the reaction crucible 102. The reaction crucible 102 (also referred to as a susceptor or growth cell) defines the crystal growth chamber 104. The reaction crucible 102 may be, at least in part, a graphite structure or other material suitable for high-temperature crystal growth. The crystal growth chamber 104 may include a plurality of zones, such as a first zone 106 and a second zone 108, as depicted in FIG. 1.

The first zone 106 can be a region where a bulk crystal 120 is grown, and the second zone 108 can be a region containing the source material 110. A heater 118 can be thermally coupled to the crystal growth chamber 104. The heater 118 can be, for example, an induction coil or a resistive heating element, and can be configured to establish and control a temperature gradient between the first zone 106 and the second zone 108.

The second zone 108 can include a silicon carbide vapor source material 110. The silicon carbide vapor source material 110 can be a material that sublimates to form a vapor for a PVT process. For example, the silicon carbide vapor source material 110 can be silicon carbide powder or a solid silicon carbide material. Throughout this disclosure, the silicon carbide vapor source material described in the various embodiments may be provided in any suitable form, including but not limited to, powders, pellets, sintered solids, porous structures, composite shaped structures, and/or as 3D-printed articles. A source material holder 112 can be used to support the silicon carbide vapor source material 110 within the second zone 108. The holder 112 can be a crucible, dish, or pedestal made from a material able to withstand high temperatures, such as graphite.

The first zone 106 can contain a seed crystal 116. The seed crystal 116 can provide a template for the growth of a bulk crystal 120. The seed crystal 116 can be positioned using the seed holder 114. The seed holder 114 can be a structure configured to mount the seed crystal 116 at a specific location within the growth chamber 104.

During a PVT process, a temperature T1 of the first zone 106 is less than a temperature T2 of the second zone 108. The temperature T1 and the temperature T2 may each be in a temperature range of about 1200° C. to about 2600° C., such as about 1500° C. to about 2600° C., such as about 1700° C. to about 2600° C. This thermal gradient causes the vapor that sublimates from the silicon carbide vapor source 110 to form the bulk crystal 120 on the seed crystal 116 during the PVT process. As shown, the seed crystal 116 may contain one or more defects 122 on a surface of the seed crystal 116. These defects 122 can represent any surface or subsurface imperfections, for example, scratches, contamination, and/or crystallographic defects. These defects 122 are at the interface between the seed crystal 116 and the bulk crystal 120. As such, the defects 122 can lead to the formation of defects 124 in the bulk crystal 120. The defects 124 can be, for instance, micropipes, threading screw dislocations, threading edge dislocations, basal plane dislocations, stacking faults, point defects, polytype inclusions, low-angle grain boundaries, voids, and/or particulate inclusions.

Throughout this disclosure, the “first zone” is the region within the crystal growth chamber configured to contain the crystalline material upon which growth is to occur (e.g., the seed crystal 116 or bulk crystal 120). Correspondingly, the “second zone” is defined as the region configured to contain the silicon carbide vapor source material 110 for sublimation. These definitions apply regardless of the physical orientation of the zones within the crucible.

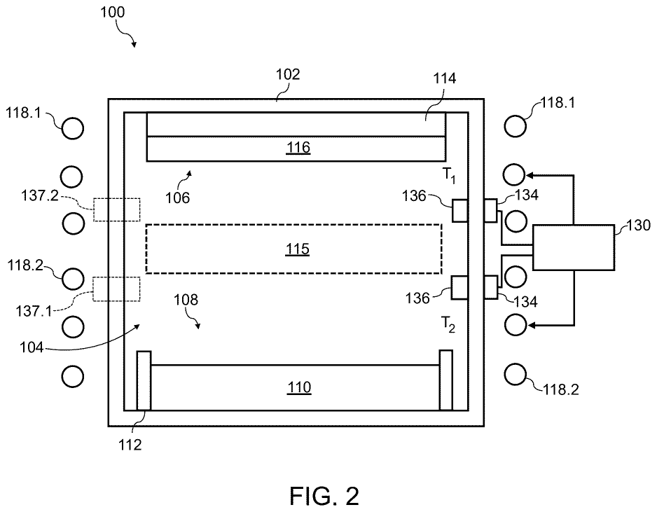

FIGS. 2 through 20 illustrate various example embodiments of crystal growth systems and methods according to examples of the present disclosure. It is to be understood that while these embodiments may differ in their physical configuration, component arrangement, or specific mode of operation (e.g., standard PVT versus continuous feed PVT (CF-PVT)), the systems and methods each may use a controlled inverted temperature gradient (T1>T2) in the presence of an etching agent to perform an in situ etch of a crystalline material, thereby improving final crystal quality.

FIG. 2 is a cross-sectional schematic diagram of a crystal growth system 100 adapted for use in a crystal growth process and crystalline material etching process of the type contemplated by certain embodiments of the disclosure. The crystal growth system 100 includes a reaction crucible 102 (also referred to as a susceptor or growth cell) that at least partially defines a crystal growth chamber 104. The reaction crucible 102 may be, at least in part, a graphite structure. The crystal growth chamber 104 may include a plurality of zones, such as a first zone 106 and a second zone 108, as depicted in FIG. 2. It will be understood that the crystal growth chamber 104 may include any number of zones, such as 3 zones, 4 zones, 5 zones, and the like.

An individual zone of the plurality of zones, such as the first zone 106 or the second zone 108, may be associated with a processing profile such that the differing zones are associated with different processing profiles. For instance, the first zone 106 can be associated with a first processing profile, and the second zone 108 can be associated with a second processing profile that is different from the first processing profile. The first processing profile of the first zone 106 may include a first temperature T1 or a first temperature profile (e.g., temperature gradient), a first pressure, and/or a first vapor transport flux. The second processing profile of the second zone 108 may include a second temperature T2 or second temperature profile (e.g., temperature gradient), a second pressure, and/or second vapor transport flux.

The first temperature profile of the first zone 106 may be the same as, or different from the second temperature profile of the second zone 108. For instance, the first temperature profile may be provided in a temperature range of about 1200° C. to about 2600° C., such as about 1500° C. to about 2600° C., such as about 1700° C. to about 2600° C. The first temperature profile may refer to thermal energy provided in the form of an axial thermal gradient, radial thermal gradient, etc. such that a gradual temperature differential is formed in the first processing profile with respect to a source material 110 and a boundary of the first zone 106.

The second temperature profile may be provided in a temperature range of about 1700° C. to about 2600° C., such that the second temperature profile of the second zone 108 is different than the first temperature profile of the first zone 106. The second temperature profile may refer to thermal energy provided in the form of an axial thermal gradient, a radial thermal gradient, etc. such that a gradual temperature differential is formed in the second processing profile with respect to a seed crystal 116 and a boundary of the second zone 108.

In some examples, the first temperature profile may be optimized or tailored to provide a desired radial thermal gradient and the second temperature profile may be optimized or tailored to provide a desired axial thermal gradient, or vice versa.

In some examples, the first zone 106 may have a first pressure and the second zone 108 may have a second pressure that is different from the first pressure. In some embodiments, the second pressure is less than the first pressure. In some embodiments, the second pressure is greater than the first pressure. In some embodiments, each of the first zone 106 and the second zone 108 may be associated with an independent pumping circuit or other pressure regulation circuit to independently regulate the pressure in the first zone 106 relative to the second zone 108. For instance, the first zone 106 may be associated with a first optional pumping port 137.1 and the second zone 108 may be associated with a second optional pumping port 137.2. In some examples, different gases and/or gas compositions may be provided into the first zone 106 relative to the second zone 108. For instance, the independent pumping ports 137.1, 137.2 for each of the first zone 106 and the second zone 108 may provide carbon-containing gases, silicon-containing gases, dopant-containing gases (e.g., n-type dopants, such as nitrogen-containing gas, phosphorus-containing gases; and/or p-type dopants, such as boron-containing gases, aluminum-containing gases), and/or other reactive or non-reactive gases. In some examples, the independent pumping ports 137.1, 137.2 for each of the first zone 106 and the second zone 108 may provide different flux, local pressure, and/or composition in the first zone 106 relative to the second zone 108. Inlet(s), outlet(s), and/or pump(s) for the pumping ports 137.1, 137.2 can be located in any suitable arrangement in the growth chamber 104, such as on the top, side, bottom, etc.

A seed holder 114 may be configured to position the seed crystal 116 in the crystal growth chamber 104. As depicted in FIG. 1, the seed crystal 116 may be positioned in the second zone 108 of the crystal growth chamber 100. The crystal growth system 100 includes a silicon carbide vapor source material 110 in a source material holder 112 in the second zone 108 of the crystal growth chamber 100. During a crystal growth process, silicon carbide vapor or other vapor may be transported from the source material 110 to the seed crystal 116 to grow a crystalline material boule on the seed crystal 116. The source material 110 may be a powdered silicon carbide source material, solid silicon carbide source material, carbon and/or silicon source material, etc. Example silicon carbide source materials are disclosed in U.S. application Ser. No. 18/963,103, filed on Nov. 27, 2024 and in U.S. application Ser. No. 18/963,117, filed on Nov. 27, 2024, both of which are incorporated herein by reference. In some examples, the source material may include an etching agent as described herein.

For instance, in some examples, the silicon carbide source material includes a shaped solid silicon carbide source material structure. In some embodiments, the structure may have a composite shape. As used herein, “composite shape” and “composite shaped” refer to any three-dimensional object or component that deviates from a regular cylindrical shape, or a composite solid structure containing multiple shaped solids which may have simple or complex shapes. Deviations from a cylindrical shape include forms with regular or irregular geometries that do not conform to the typical circular or elliptical cross-section of a cylinder. Such structures may exhibit various shapes, including but not limited to structures with polygonal cross-sections; irregularly curved structures; and shapes with holes, voids, surface variations, or combinations thereof. The term also includes shapes containing multiple interconnected or distinct substructures. The substructures may themselves be composite shaped or may be cylindrically shaped. The term encompasses a wide range of geometric configurations and excludes objects that maintain a uniform cylindrical profile throughout their entire volume.

As used herein, “shaped solid” and “solid structure” refer to non-powdered solid components. A non-powdered component, for example, can have a size in at least one dimension of about 1 μm or greater, such as about 10 μm or greater, such as about 50 μm or greater, such as about 100 μm or greater, such as about 200 μm or greater, such as about 1000 μm or greater, such as about 1700 μm or greater, such as about 5 mm or greater, such as about 10 mm or greater. In some example embodiments, a shaped solid or solid structure may be formed by binding powdered particles together to form a composite material. Shaped solids may be shaped in an intentional manner to influence relevant properties, such as sublimation rate, vapor flow paths, thermal gradients, etc. Shaped solids may have one or more shape modifications. Shape modifications are intentional modifications to a source structure to influence relevant properties, such as sublimation rate, vapor flow paths, thermal gradients, etc.

In some embodiments, a composite shaped structure may include complex geometry including shapes, features, symmetry, asymmetry, dimensions, thicknesses, and/or appendages to improve such parameters. In some embodiments, the shaped solid source material may have features that provide desired thermal gradients within the source material. In some embodiments, the shaped solid source material may have features that provide high surface area for better sublimation rates. In some embodiments, the shaped solid source material may have features that provide desired gas flow paths through the source material to efficiently transport the sublimated silicon carbide. In some embodiments, the shaped solid source material may have features that are tailored based on known local variations (e.g., temperature variations) within the crucible. In some embodiments, the shaped solid source material may have features that allow for directional control of the gas flow or heat flow within the source. In some embodiments, the shaped solid source material may have features that allow for control of the sublimation rate over time. Such features are described in more detail below with reference to the drawings.

The source material can be intentionally shaped to control the sublimation rate over time and thus during various stages of crystal growth. The source material can also be shaped to obtain a desired vapor flow/local vapor pressure relative to the seed/growing crystal surface.

In some embodiments, the silicon carbide source material structure may contain multiple layers varying in at least one property. For example, it may include an outer layer and an inner layer such that when used in a sublimation process, the outer layer sublimates first, followed by the inner layer. Varying the properties of the layers can affect the sublimation properties (e.g., rate, temperature) and crystal growth properties (e.g., polytype, dopant concentration, defect concentration, shape, growth rate).

In some embodiments, the silicon carbide source material structure includes a dopant. The inclusion of a dopant in the source material provides a method for incorporating the dopant into the silicon carbide crystal. This is particularly useful for incorporating dopants which are not easily incorporated using a vapor source.

As depicted in FIG. 2, the system may include an interface structure 115 between the first zone 106 and the second zone 108. In some examples, such as the example depicted in FIG. 2, the interface structure 115 may physically separate the first zone 106 and the second zone 108. In some examples, the interface structure 115 is positioned at a location in the reaction crucible 102 that is closer to the seed holder 114 relative to the source material 110. In some examples, the interface structure 115 may be positioned in a range of about 0.5 cm to about 10 cm from the seed holder 114, such as about 1 cm to about 6 cm, such as about 3 cm to about 5 cm. In some examples, the interface structure 115 may include a baffle structure. The baffle structure may be graphite (e.g., porous graphite, coated graphite, etc.). The baffle structure may have one or more apertures or may be made from a porous material to allow for the passage of vapor. Example baffle structures that may be used are disclosed in U.S. patent application Ser. No. 18/962,454, filed on Nov. 27, 2024, which is incorporated herein by reference. Any of the interface structures provided herein may extend across a portion or all of the width or flux path of a growth chamber.

For instance, in some examples, the baffle structure includes a porous material, such as porous graphite. In some examples, at least a portion of the baffle structure has a porosity of greater than about 50% by volume, such as greater than about 70% by volume, such as greater than 80% by volume. Porosity by volume expressed as a percentage refers to the percentage of the volume of voids in the baffle relative to the total volume of the material. In some embodiments, the baffle has a porosity in a range of about 50% to about 97%, such as about 80% to about 97%, such as about 85% to about 97%.

In some embodiments, the baffle structure includes one or more apertures defined through a thickness of the baffle. As used herein, an “aperture” is a defined opening, space, perforation, hole, or void in a structure that extends from one exterior surface of a structure to another exterior surface of the structure. In some embodiments, the baffle has a long dimension that is generally non-perpendicular to the growth surface of the seed crystal. In some examples, the one or more apertures include a plurality of holes defined through the baffle. In some examples, the one or more apertures include an annular aperture defined through a thickness of the baffle. In some examples, a vapor transport direction through the one or more apertures is in a non-perpendicular direction relative to the growth surface of the seed crystal.

In some examples, the one or more apertures are arranged in the baffle to provide for non-uniform vapor transport from the source material to the seed crystal. In some examples, the one or more apertures are arranged in the baffle to provide for asymmetric vapor transport from the source material to the seed crystal. In some examples, the one or more apertures include a first aperture and a second aperture, wherein a width of the first aperture is different from a width of the second aperture. In some examples, the one or more apertures include a first plurality of apertures and a second plurality of apertures, wherein a density of the first plurality of apertures in the baffle is different from a density of the second plurality of apertures in the baffle.

In some examples, the baffle includes a plurality of dividers arranged in a non-perpendicular direction relative to the growth surface of the seed crystal. In some examples, the one or more apertures are arranged to direct vapor in a direction that is more towards a center of the seed crystal relative to a peripheral portion of the seed crystal. In some examples, the one or more apertures are arranged to direct vapor in a direction that is more towards a peripheral portion of the seed crystal relative to a central portion of the seed crystal.

In some examples, the baffle includes a plurality of baffle structures (e.g., baffle plates). In some examples, the baffle includes a first baffle plate having the one or more apertures and a second baffle plate with no apertures. In some examples, the baffle includes a first baffle plate comprising a first aperture and a second baffle plate comprising a second aperture. In some examples, the first aperture is aligned with the second aperture. In some examples, the first aperture is not aligned with the second aperture.

In some examples, one or more portions of the baffle element, coating, surface or subsurface treatment for the baffle or any of its parts may include an engineered structure having a construction or configuration that is or includes one or more of a porous structure, woven wire, perforated plate, foam, screen printed material, refractory metal, 3D printed structure, coated wire, carbon fiber mesh, carbon wires, refractory metal wires, woven mesh, cast component(s), grid, sintered powder, composite laminate, electroformed structure, braided wire, honeycomb structure, felt structure, nanostructured film, carbon nanotubes, tightly or loosely interconnected network of structures or other suitable construction or configuration. Portions or the entirety of any of the foregoing may be coated, treated and/or converted to form a metal carbide surface, subsurface or entire article of metal carbide. One or more combinations of any of these constructions or configurations may be used without deviating from the scope of the present disclosure. For example, in some embodiments, a first baffle structure (e.g., a first baffle plate) may include a first configuration (e.g., porous material) and a second baffle structure (e.g., a second baffle plate) may include a second configuration (e.g., honeycomb structure). In some examples, the baffle structure may be a secondary source or may comprise a secondary source, such as a secondary carbon source (e.g., if the interface structure comprises graphite).

In some examples, the interface structure 115 may be positioned such that a first vapor transport flux (e.g., F1, a first matter transport rate) in the first zone 106 is different than a second vapor transport flux (e.g., F2, a second matter transport rate) in the second zone 108. In some examples, the first vapor transport flux (e.g., F1) is less than the second vapor transport flux (e.g., F2) such that an energetic incentive is provided to source vapor to deposit on the growth front of the seed crystal 116 rather than another portion of the crystal growth chamber 104, such as the interface structure 115. Modifications of the processing profile (e.g., temperature profile, chemical environment, pressure, kinetics factors such as transport path, etc.) through the position of the interface structure 115 may enhance deposition of source vapor from the source material 110 on the seed crystal 116 to grow the crystalline material boule.

Further, by physically separating the first zone 106 and the second zone 108, the interface structure 115 may reduce a thermal interaction between at least two zones of the plurality of zones. Thermal interactions in a crystal growth process may lead to variations or fluctuations in a thermal processing profile, which may alter a thermal gradient established between the source material 110 and the seed crystal 116. Additionally, variations in a thermal processing profile may impact growth uniformity, defect formation, and mass transport (e.g., vapor flux). It is desirable to have stable, consistent thermal processing profiles in a crystal growth system. In some examples, the first zone 106 and the second zone 108 may not be separated by a physical structure, but rather, the first zone 106 and the second zone 108 may be delineated by another component of the crystal growth system 100, e.g., such as a sidewall of the crucible 102 or structure on the sidewall of the crucible 102.

Referring again to FIG. 2, the first pressure of the first processing profile of the first zone 106 may be the same as, or different from the second pressure of the second processing profile of the second zone 108. For instance, modification of sublimation of the source material 110 may be achieved by modification of the first pressure of the first processing profile of the first zone 106. Modification of defect formation may be achieved by modifying the second pressure of the second processing profile of the second zone. Similarly, as discussed above, the first vapor transport flux of the first processing profile of the first zone 106 may be the same as, or different from the second vapor transport flux of the second processing profile of the second zone 108. For instance, the species, concentration, or rate of transport in the first zone 106 may be the same as, or differ from the species, concentration, or rate of transport in the second zone 108.

The crystal growth system 100 may include a first heater 118.1 adapted to heat the first zone 106. The first heater 118.1 may be an induction heater (e.g., an RF heater). Alternatively, the first heater 118.1 may be a resistive heater. Using any competent heating mechanism and approach, the temperature within the first processing profile of the first zone 106 of the crystal growth system 100 may be controllable.

Similarly, the crystal growth system 100 may include a second heater 118.2 adapted to heat the second zone 108. The second heater 118.2 may be an induction heater (e.g., an RF heater). Alternatively, the second heater 118.2 may be a resistive heater. Using any competent heating mechanism and approach, the temperature within the second processing profile of the second zone 108 of the crystal growth system 100 may be controllable.

In some examples, such as the example depicted in FIG. 2, the first heater 118.1 may extend vertically about the reaction crucible 102 from a point at which the interface structure 115 is disposed in the crystal growth system 100 to a region at or beyond the seed crystal 116 or the seed holder 114. The second heater 118.2 may extend vertically about the reaction crucible 102 from a point at which the interface structure 115 is disposed in the crystal growth system 100 to a region at or beyond the source material 110. In some examples, the first heater 118.1 and the second heater 118.2 may not extend past the interface structure 115 or other reactor component that delineates the crystal growth chamber 104 into the plurality of processing zones.

In some examples, at least one of the first heater 118.1 or the second heater 118.2 may have a non-uniform density of heat distribution elements. For instance, the first heater 118.1 may have a non-uniform density of coils disposed about the first heater 118. The first heater 118.1 may include variations in material properties in the heat distribution elements that impact the transfer of thermal energy along a portion of the first heater 118.1. The first heater 118.1 may include intentional design features to impede or enhance the transfer of thermal energy along a portion of the first heater 118.1. Similarly, the second heater 118.2 may have a non-uniform density of coils disposed about the second heater 118.2. The second heater 118.2 may include variations in material properties in the heat distribution elements that impact the transfer of thermal energy along a portion of the second heater 118.2. The second heater 118.2 may include intentional design features to impede or enhance the transfer of thermal energy along a portion of the second heater 118.2. The non-uniform density of heat distribution elements may have a highest density of heat distribution elements or transfer of thermal energy at a point nearest the interface structure 115.

In some examples, such as the example depicted in FIG. 2, at least one of the first heater 118.1 or the second heater 118.2 may be movable during a crystal growth process with respect to the reaction crucible 102 or other components of the crystal growth system 100. For instance, the first heater 118.1 may be configured to move in a vertical direction. The second heater 118.2 may be configured to move in a vertical direction. In some examples, the first heater 118.1 may be moved independently of the second heater 118.2. For instance, the first heater may be moved based on process parameters associated with the first zone 106. The second heater 118.2 may be moved based on process parameters associated with the second zone 108. In some examples, the first heater 118.1 and the second heater 118.2 may be moved together as one unit at the same time. In some examples, the crucible 102 may be moved relative to the first heater 118.1 and/or the second heater 118.2.

The crystal growth system 100 may include a controller 130 comprising one or more control devices 130. As used herein, the term “controller” is to be interpreted broadly and may refer to a single, centralized control unit or a distributed control system comprising a plurality of controllers, control circuits, or processing units that operate independently or in coordination. The controller 130 may be configured to control one, some, or all of the functions and components of the crystal growth system 100, either individually or in combination. For example, a single integrated controller may manage all system operations, or alternatively, dedicated controllers may be assigned to manage specific subsystems (e.g., a thermal controller, a mechanical motion controller, a gas flow controller) and may communicate with each other or with a central coordinating controller.

The controller 130 may comprise processing circuitry including, but not limited to, one or more microprocessors, microcontrollers, digital signal processors (DSPs), application-specific integrated circuits (ASICs), field-programmable gate arrays (FPGAs), programmable logic controllers (PLCs), a system on a chip (SoC), or a general-purpose computer system. The functionality of the controller 130 may be implemented in hardware, software, firmware, or any combination thereof. In embodiments utilizing programmable logic, the controller 130 is operable to execute instructions stored in one or more associated non-transitory computer-readable memory devices (e.g., RAM, ROM, flash memory) to implement the methods and control operations described herein. The controller 130 may further include input/output (I/O) interfaces for communicating with the various sensors, actuators, power supplies, user interfaces, and other components of the crystal growth system 100.

In some embodiments, the controller 130 may be operable to independently control the first heater 118.1 or second heater 118.2. The crystal growth system 100 may include at least one sensor 134. As depicted in FIG. 2, the sensor 134 may be positioned such that data is obtained for a processing profile parameter (e.g., temperature, pressure, flux, etc.) in at least one of the first zone 106 or the second zone 108. The crystal growth system 100 may include a sensor window 136 positioned on the crucible. In some examples, the sensor window 136 may include quartz. In some examples, the sensor window 136 may include sapphire. The sensor 134 may be one or more of a pyrometer, thermocouple, non-contact sensor or other suitable sensor. The controller 130 may be operable to independently control at least one of the first heater 118.1 or the second heater 118.2 based on data obtained from the sensor 134. In addition, and/or in the alternative, the first heater 118.1 or the second heater 118.2 may be jointly controlled (e.g., at a fixed proportion of power delivery). In some examples, the first heater 118.1 and/or the second heater 118.2 may be controlled such that the first heater 118.1 or the second heater 118.2 provide continuous thermal output (e.g., a thermal gradient may be established and remain unchanged in a respective zone during a crystal growth process).

In some examples, the one or more sensors 134 may include a first sensor associated with the first zone 106 and a second sensor associated with the second zone 108 as illustrated in FIG. 1. In some embodiments, the sensor(s) 134 may be associated with a first zone, second zone, other zone, or interface structure between zones. In some embodiments, the sensor(s) 134 can be associated with single or multiple zones and positioned in single or multiple locations across multiple zones or between zones or at an interface structure. It will be understood that the controller 130, the one or more sensors 134, and/or the sensor window 136 may be included in any of the examples provided herein.

In some examples, the crystal growth system 100 may include one or more actuators. The actuators may be configured to impart translational and/or rotational movement to one or more components of the crystal growth system 100, such as the seed holder 114 and seed crystal 116, the source material 110, the insulation of the crucible 102, the heating elements 118.1, 118.2, the interface structure 115, the crucible 102, and/or other elements. The actuator(s) may include any suitable type of actuator, such as an electric actuator (e.g., servo motor, stepper motor, linear motor, DC motor, AC motor, rotary motor), piezoelectric actuator, pneumatic actuator (e.g., pneumatic cylinder, pneumatic diaphragm), hydraulic actuator (e.g., hydraulic cylinder), electromagnetic actuator (e.g., solenoid), thermal actuator (e.g., shape memory alloy actuator, bimetallic actuator), vacuum actuator (e.g., vacuum suction actuator) and/or other suitable actuator, rotary actuator (e.g., screwing arrangement). The actuator(s) may operate independently of each other to cause relative positioning of components relative to other components.

For instance, in some embodiments, the source material 110 may be rotated independently of the seed crystal 116. In some embodiments, one or more actuators may be operable to move crystalline material grown on the seed crystal 116 (e.g., the growth face of the crystalline material) to different vertical positions relative to the source material 110 during a crystal growth process. For instance, one or more actuators may move the crystalline material and/or the source material 110 such that there is a first transport distance between the crystalline material and the source material 110 for a first process period. One or more actuators may move the crystalline material and/or the source material 110 such that there is a second transport distance (e.g., different from the first transport distance) between the crystalline material and the source material 110 for a second process period. Those of ordinary skill in the art, using the disclosure provided herein, will understand that any type of actuator may be used to move components without deviating from the scope of the present disclosure. The actuator(s) may be used in any of the crystal growth systems provided herein.

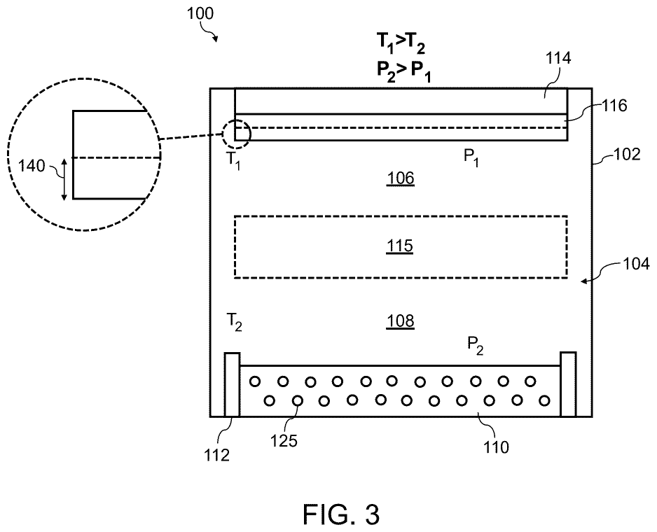

FIG. 3 depicts an example implementation of a crystal growth system 100 (e.g., the crystal growth system of FIG. 2) during an in-situ etching process according to example embodiments of the present disclosure. The crystal growth system 100 can include a reaction crucible 102 that defines a crystal growth chamber 104. The crystal growth chamber 104 can include a first zone 106 and a second zone 108 (e.g., separated by an optional interface structure 115). The first zone 106 can include a seed crystal 116 supported by a seed holder 114. The second zone 108 can contain a silicon carbide vapor source material 110, which, in some embodiments, can include an etching agent 125, supported by a source material holder 112.

As discussed, the crystal growth system 100 may include an etching agent 125 in the crystal growth chamber 104. The etching agent 125 can be a substance provided within the crystal growth chamber 104 to facilitate an in situ surface etching process on a crystalline material, such as a seed crystal or a bulk crystal. In some embodiments, the etching agent 125 can be a silicon vapor from a silicon vapor source, such as elemental silicon, silicon powder, or a compound like Si₃N₄. In some embodiments, the etching agent 125 is an introduced gas, such as nitrogen, hydrogen, carbon monoxide, a hydrocarbon (e.g., methane), or a silicon-containing gas (e.g., silane). In some embodiments, the etching agent 125 is a metal vapor from a metal vapor source (e.g., powder or solid metal vapor source) comprising one or more rare earth elements such as lanthanum, cerium, praseodymium, or neodymium. The etching agent 125 may be located in various positions within the system 100, such as being integrated with the silicon carbide vapor source material 110 to form a composite source (e.g., silicon and silicon carbide composite structure), interspersed as a powder within a powdered silicon carbide vapor source, placed in a dedicated etching agent holder 127 separated from the source material 110, positioned at the interface structure 115, and/or introduced via a gas inlet 160.

FIG. 3 illustrates the operation of the crystal growth system 100 to implement an in situ etching process on the seed crystal 116. This process is designed to remove a damaged and contaminated surface layer from the seed crystal 116 before starting bulk crystal growth. More particularly, FIG. 3 depicts an inverted temperature gradient condition, where a first temperature T1 in the first zone 106 is greater than a second temperature T2 in the second zone 108. This setup induces a controlled etching of the surface of the seed crystal 116, removing the compromised layers. A callout illustrates an etched depth 140, which represents the thickness of material removed from the seed crystal 116 during this process. In some embodiments, the etched depth 140 may be in a range of about 10 to 100 microns of material, such as about 15 microns to about 50 microns, such as about 15 microns to about 30 microns.

A challenge when etching the silicon carbide seed crystal 116 is preventing graphitization, which is the formation of a detrimental solid carbon layer on the seed surface from the decomposition of silicon carbide (SiC(solid)→Si(gas)+C(solid)). According to examples of the present disclosure, an etching agent 125, which is shown in FIG. 3 as being integrated with the silicon carbide vapor source material 110, can be used to enhance the etching of the seed crystal 116 and/or reduce graphitization.

For instance, in the example where the etching agent 125 comprises silicon, such as elemental silicon, the etching agent 125 increases the silicon vapor pressure within the crystal growth chamber 104. For the etching to proceed without causing graphitization, the second silicon vapor pressure P2 generated from the etching agent 125 at the source material 110 is higher than the equilibrium silicon vapor pressure P1 over the hotter surface of the seed crystal 116. This condition (second silicon vapor pressure P2>first silicon vapor pressure P1) suppresses the graphitization reaction and instead promotes a cleaner etch of the seed via an alternative pathway, such as SiC(solid)+Si(gas)→Si₂C(gas). In some aspects, the etch rate can be controlled by the seed temperature T1 and the magnitude of the temperature difference (T1−T2).

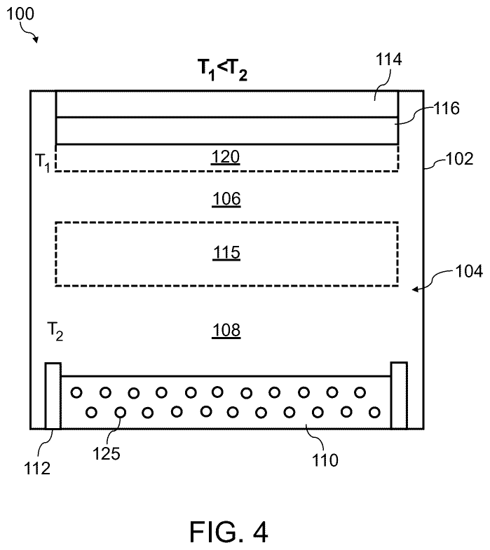

FIG. 4 depicts the same crystal growth system 100 shown in FIG. 3, but now configured to implement a PVT process for bulk crystal growth following the in situ etching process. The system includes the reaction crucible 102 defining the crystal growth chamber 104, which is divided into a first zone 106 and a second zone 108 (e.g., by an optional interface structure 115). The first zone 106 contains the seed crystal 116, which now has an etched surface. The second zone 108 contains the silicon carbide vapor source material 110 integrated with the etching agent 125. This figure illustrates the growth of a bulk crystalline material 120 on the prepared seed crystal 116.

To transition from the etching process (FIG. 3) to the growth process, the temperature gradient within the crystal growth chamber 104 is inverted. Specifically, the controller adjusts the heaters so that the first temperature T1 in the first zone 106 is now less than the second temperature T2 in the second zone 108 (T1<T2). This forward temperature gradient is the condition for a PVT process.

With the forward temperature gradient established (T1<T2), the hotter silicon carbide vapor source material 110 sublimates, releasing vapor species into the crystal growth chamber 104. Driven by the thermal gradient, these vapor species travel from the hotter second zone 108 to the cooler first zone 106, where they deposit onto the clean surface of the seed crystal 116. This controlled deposition process grows a bulk crystalline material 120 on the seed, replicating its crystal structure. Because the growth begins on a crystallographically improved surface that is free of the initial subsurface damage and contamination, the propagation of defects from the seed into the bulk crystalline material 120 is reduced, leading to a final product with a much lower defect density and higher quality.

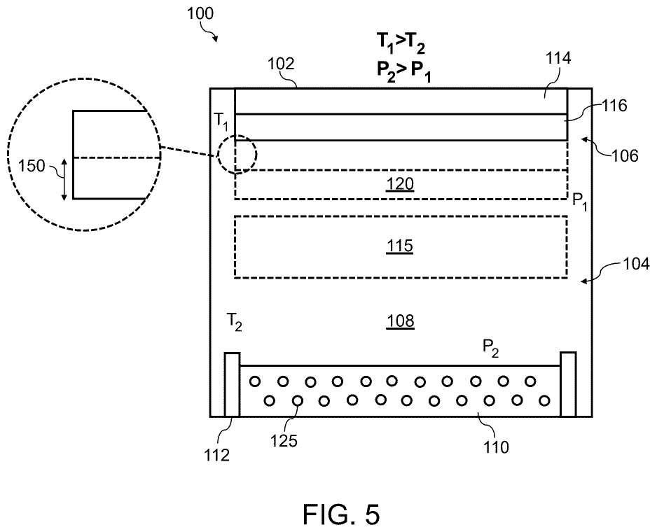

FIG. 5 illustrates the crystal growth system 100 configured to perform a second etching process (e.g., subsequent in situ etching process), this time on the bulk crystalline material 120 grown on the seed crystal 116. This process demonstrates the capability of the crystal growth system 100 to perform mid-growth correction by pausing the growth process and cleaning/etching the newly formed crystal surface. The system components remain the same, including the reaction crucible 102, crystal growth chamber 104, first zone 106, and second zone 108. The operation shown is the removal of a surface layer from the bulk crystal 120, represented by the etched depth 150 in the callout. In some embodiments, the etched depth 150 may be in a range of about 10 to 100 microns of material, such as about 15 microns to about 50 microns, such as about 15 microns to about 30 microns.

To perform this intermediate etching, the growth process is paused, and the temperature gradient is inverted once again to re-establish the etching condition. A controller manipulates the heaters to make the first temperature T1 at the surface of the bulk crystal 120 greater than the second temperature T2 at the source material 110 (T1>T2). This is the same inverted temperature gradient used for the initial seed etch shown in FIG. 3.

This inverted temperature gradient (T1>T2) causes the surface of the newly grown bulk crystal 120 to be etched. This operation may be used to remove any defective layers or contamination that may have formed on the growing surface due to process fluctuations. As with the initial seed etch, the presence of the etching agent 125 and the resulting higher silicon vapor pressure (P2>P1) facilitates a clean removal of material with reduced graphitization. After the desired etched depth 150 is removed, the gradient can be inverted yet again to the growth condition (T1<T2) to resume growing the bulk crystal on the refreshed surface. This ability to perform mid-growth correction reduces the risk of transient issues compromising the entire crystal and can lead to a final product with a much lower overall defect density.

In addition to preparing the seed crystal surface, some aspects of the present disclosure are directed to reducing defects that originate from the silicon carbide vapor source material 110 itself. It has been found that a significant source of SOG defects can be impurities that evaporate from the source material and subsequently poison the seed crystal surface. These impurities often include oxides and related compounds which are mobile at PVT growth temperatures.

To address this, certain embodiments utilize an in-situ chemical pre-conditioning treatment to clean the source material. This method involves providing a source conditioning agent comprising a metal-containing additive directly within or intermixed with the silicon carbide vapor source material 110 to form a composite source. The additive is chosen to vaporize at a moderate temperature during the initial heat-up ramp of the crucible, before the silicon carbide source material begins to sublimate for bulk growth. The resulting metal vapor reacts with and removes oxygen-related impurities from the surfaces of the source material grains. This pre-conditioning may clean the source material before the impurities can be transported to the seed crystal 116, thereby reducing seed surface contamination and reducing SOG defects.

Suitable metal-containing additives are selected to react with surface oxides without being incorporated as detrimental impurities into the grown crystal. Example additives include, but are not limited to, calcium, strontium, barium, tin, bismuth, lead, lanthanum, cerium, praseodymium, or neodymium. Most of the listed metals have very low known or suspected solubility in silicon carbide. Alternatively, while tin has a moderately higher solubility than the others, it is a neutral dopant that should not alter the crystal's electrical properties.

In some embodiments, the metal-containing additive can be supplied in various forms, including but not limited to, a pure metal, a reduced metal, a metal carbonate, an oxide, a silicate, a carbide, or other suitable metal compound. In embodiments where the additive is provided, for instance, as a metal oxide, it may be combined with an oxygen-getter such as elemental carbon or silicon. This combination can mitigate the release of oxygen at lower temperatures during the initial heat-up phase of the process.

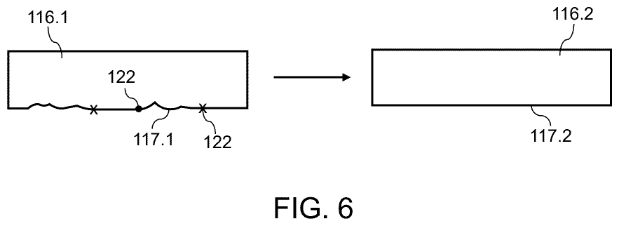

FIG. 6 illustrates an example schematic of an etching process on a crystalline material. FIG. 6 shows a crystalline material 116.1 before etching, which can have a surface 117.1 with one or more defects 122. FIG. 6 also shows the crystalline material 116.2 after etching, which can have an etched surface 117.2 from which the defects 122 may have been removed.

The crystalline material before etching 116.1 can represent a crystalline material, such as a seed crystal or a bulk crystalline material, prior to an in-situ etching process. A surface 117.1 can be a surface of the crystalline material before etching 116.1. The surface 117.1 can be characterized by topographical irregularities and may contain one or more defects 122. The defects 122 can represent any type of surface or subsurface imperfection. For example, defects 122 can include scratches, contamination, or crystallographic imperfections.

The crystalline material 116.2 after etching can represent the state of the crystalline material after an etching process has been applied. The crystalline material 116.2 after etching can have an etched surface 117.2. The etched surface 117.2 can be a surface from which a layer of material, which may have included the surface 117.1 and defects 122, has been removed. The etched surface 117.2 can have reduced defects relative to the surface 117.1.

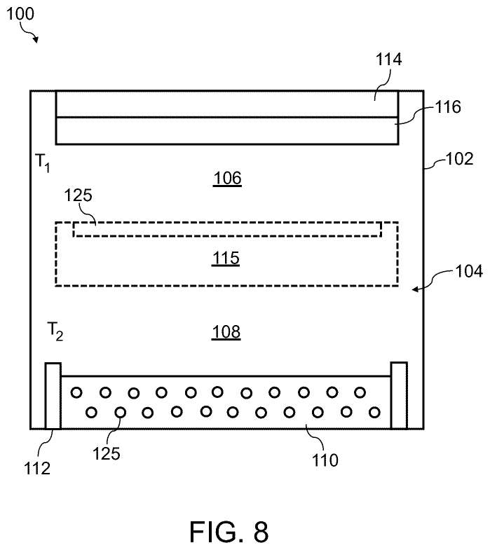

The etching agent 125 used to facilitate the in situ etching process according to example embodiments of the present disclosure may be provided to the crystal growth system 100 in any number of ways without deviating from the scope of the present disclosure. FIGS. 8-11 depict various embodiments having different methods and/or systems for introducing the etching agent 125 according to examples of the present disclosure.

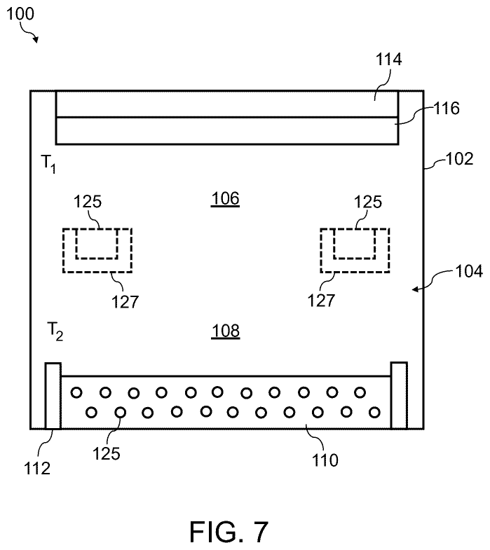

FIG. 7 illustrates an example embodiment of the crystal growth system 100, showcasing a different method for providing the etching agent 125. In this configuration, the etching agent 125 is placed in one or more dedicated etching agent holders 127, which are physically separated from the silicon carbide vapor source material 110. The other components of the system 100, including the reaction crucible 102, first zone 106 with the seed crystal 116, and second zone 108 with the source material 110, remain as previously described.

The etching agent holder 127 is a container or structure designed to hold the etching agent material, such as elemental silicon, Si₃N₄, or a metal vapor source, within the high-temperature environment of the crystal growth chamber 104. The etching agent holder 127 is illustrated as an annular structure within the growth chamber for illustrative purposes. The etching agent holder 127 can be made from any suitable material, such as graphite, and may have any shape or configuration suitable for the controlled sublimation and distribution of the etching agent.

While FIG. 7 shows one possible location for the etching agent holder 127 within the growth chamber 104, the etching agent holder 127 can be positioned anywhere in the chamber 104 where it can release its vapor to facilitate the etching process. During an etching cycle (T1>T2), the etching agent may sublimate from this separate holder to create the vapor pressure conditions for an etch of the crystalline material with reduced graphitization.

FIG. 8 shows yet another example implementation of the crystal growth system 100, providing another example for positioning the etching agent 125. In this embodiment, the etching agent 125 is located at the interface structure 115, which is positioned between the first zone 106 and the second zone 108. This placement offers a different way to control the distribution of the etching vapor within the crystal growth chamber 104. As shown in the figure, this configuration can be used alone or in combination with having the etching agent 125 also integrated with the silicon carbide vapor source material 110.

As described above, the interface structure 115 is a physical component, such as a baffle, porous plate, or screen, that influences the transport of heat and vapor between the two zones. By positioning the etching agent 125 (e.g., a silicon vapor source or a metal vapor source) directly on this structure, its vapor can be introduced into the region between the source material 110 and the seed crystal 116. This placement can create a well-defined and uniform vapor environment in the first zone 106 that is optimal for the etching process. When the inverted temperature gradient (T1>T2) is applied, the etching agent 125 sublimates from the interface structure 115, establishing the vapor pressure conditions to etch the surface of the crystalline material with reduced graphitization.

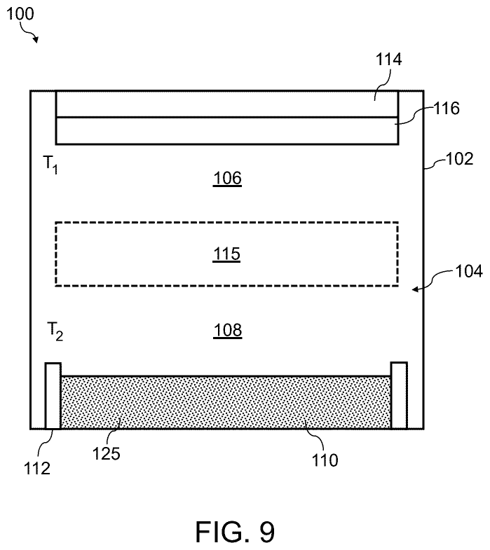

FIG. 9 illustrates an example implementation of the crystal growth system 100 where the etching agent 125 is integrated directly into the silicon carbide vapor source material 110 to form a composite source (e.g., silicon and silicon carbide composite structure). For instance, the etching agent 125, such as elemental silicon powder, being interspersed and intermixed within a powder of the silicon carbide source material 110. This composite material is then placed in the source material holder 112 within the second zone 108 of the crystal growth chamber 104. The other system components, including the reaction crucible 102 and the first zone 106 containing the seed crystal 116, are arranged as in the other examples.

In some examples, a composite source is created by mixing the powdered etching agent 125 with the powdered silicon carbide vapor source material 110. In some examples, the composite source is created by providing the etching agent 125 (e.g., powder or solid) into one or more voids or other structures of the silicon carbide vapor source material 110 (e.g., to form a silicon and silicon carbide composite structure). This approach provides that the source of the etching vapor is located alongside the source of the silicon carbide vapor.

During an in situ etching process, when the inverted temperature gradient is applied (T1>T2), the etching agent 125 sublimates from this composite mixture along with the silicon carbide. This co-sublimation efficiently generates the high partial pressure of the etching vapor (e.g., silicon vapor) needed to suppress graphitization and facilitate the etch of the crystalline material in the hotter first zone 106.

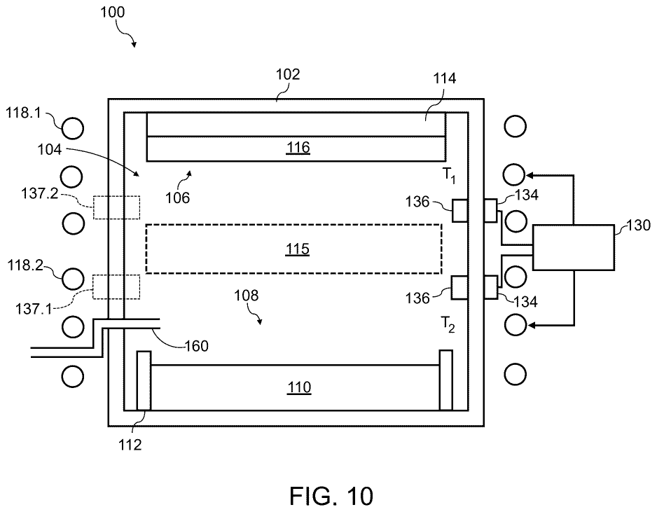

FIG. 10 illustrates an embodiment where the etching agent 125 is introduced into the crystal growth system 100 as a gas via a gas inlet 160. This configuration allows for precise, real-time control over the composition and pressure of the etching atmosphere within the crystal growth chamber 104. The figure shows the gas inlet 160 in communication with the second zone 108, along with other system control components like a first heater 118.1, a second heater 118.2, sensors 134, and a controller 130 that manages the overall process. The gas inlet 160 may be located elsewhere in the crystal growth chamber 104 without deviating from the scope of the present disclosure.

The gas inlet 160 is a port or conduit designed to introduce a gaseous etching agent into the crystal growth chamber 104. While shown in the second zone 108, the inlet can be located anywhere in the chamber to ensure optimal distribution of the gas. The etching agent introduced can be one or more gases, including nitrogen, hydrogen, carbon monoxide, a hydrocarbon (e.g., methane), sulfur-containing gas, or a silicon-containing gas (e.g., silane). The controller 130 can manage the flow of this gas to start, stop, or adjust the etching process as needed. When the inverted temperature gradient (T1>T2) is established, the introduced gas creates a reactive atmosphere that interacts with the hot crystalline surface, promoting the etch of the crystalline material.

In some embodiments, the gaseous etching agent may comprise one or more gases, including nitrogen, hydrogen, oxygen, sulfur, or carbon-containing gases like carbon monoxide or a hydrocarbon (e.g., methane). These gases can be used to alter the equilibrium Si:C ratio in the vapor within the chamber. By contributing extra silicon or carbon through the formation of gaseous species like SiO or CN at high temperatures, the stoichiometry of the vapor can be controlled to promote a reduced graphitizing etch of the seed crystal.

However, in some embodiments, the gas etching may be performed as a multi-step process. This process could first involve a thermal graphitization step, where the seed surface is intentionally graphitized by heating it without a protective atmosphere. This may be followed by a second step of chemically etching and removing the newly formed graphitic surface using one of the reactive gases described above.

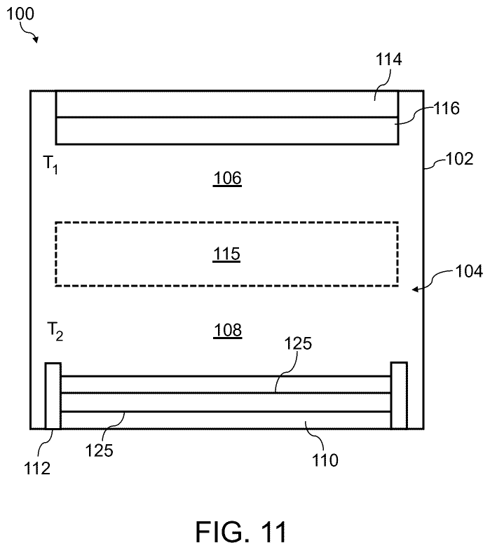

FIG. 11 illustrates an example implementation of the crystal growth system 100 where the etching agent 125 is strategically placed in layers within the silicon carbide vapor source material 110. This layered composite source is designed to facilitate periodic etching during a bulk crystal growth process, allowing for automated, timed in situ etch back cycles. The arrangement provides a method to intermittently clean the growing crystal surface without physically stopping the entire run, thereby improving the final crystal quality.

In this configuration, layers of the etching agent 125 (e.g., elemental silicon) alternate with layers of the silicon carbide vapor source material 110. The thickness and spacing of these layers are intentionally designed to control the timing of the etching process. As the source material is consumed during a growth run, each layer of the etching agent 125 is sequentially exposed. When an etching agent layer is exposed, it sublimates and increases the etching vapor pressure in the crystal growth chamber 104.

The controller can then temporarily invert the temperature gradient to the etching condition (T1>T2) to perform an in situ etch on the growing bulk crystal. This may reduce any defects that may have formed during the previous growth phase. Once the etch is complete, the gradient is switched back to the growth condition (T1<T2), and crystal growth resumes on the newly cleaned surface, consuming the next layer of silicon carbide source material. This automated cycle of growth and etching can be repeated for each layer, leading to a final bulk crystal with a lower defect density.

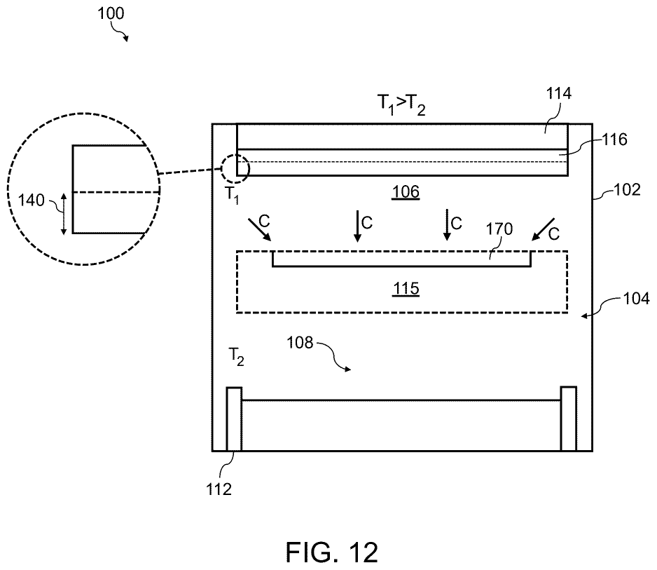

FIG. 12 is a cross-sectional schematic diagram of a crystal growth system 100 configured to perform an in-situ seed etching process using a carbon getter material as the etching agent according to example embodiments of the present disclosure. This embodiment provides a method for etching a crystalline material that does not use, in some instances, an inverted temperature gradient. As depicted, the system may operate under a normal forward temperature gradient (T₁<T₂).

The system 100 includes a carbon getter material 170, such as tantalum oxide (Ta₂O₅), positioned in the crystal growth chamber 104 between the source material 110 and the seed crystal 116. In the embodiment shown, the carbon getter 170 is located on or as part of the interface structure 115. However, the carbon getter 170 may be in other locations without deviating from the scope of the present disclosure.

During operation, the carbon getter 170 consumes elemental carbon from the surrounding environment, as illustrated by arrows labeled “C”. This chemical reaction creates a silicon-rich atmosphere in the first zone 106 near the seed crystal 116. This silicon-rich atmosphere induces a clean, non-graphitizing etch of the surface of the seed crystal 116, removing damage and contamination. A magnified callout shows an etched depth 140 being removed from the seed crystal 116 as a result of this etching process.

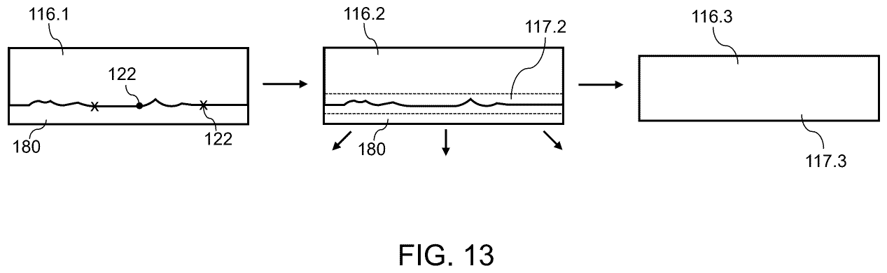

FIG. 13 is a schematic illustrating a seed preparation process using a sacrificial, evaporable coating. FIG. 13 shows a seed crystal 116.1 before the process, having a sacrificial coating 180 applied over a surface with defects 122. FIG. 13 also shows the seed crystal 116.2 during a heat-up phase, where a reaction zone 117.2 represents the etching of the defective surface by the coating 180, followed by evaporation. FIG. 13 also shows the seed crystal 116.3 after the process, with an etched surface 117.3 ready for growth.

The seed crystal before preparation 116.1 can represent a seed crystal with pre-existing surface or subsurface damage 122 prior to being loaded into a crystal growth chamber. A sacrificial coating 180 can be a layer applied to the seed surface. The reaction zone 117.2 can represent the interaction where the sacrificial coating 180 etches or dissolves the top layer of the seed crystal 116.1. The seed crystal after preparation 116.2 can represent the state of the seed crystal after the coating has etched the surface and evaporated. The seed crystal after preparation 116.2 can have an etched surface 117.3. The etched surface 117.3 can be a surface from which the sacrificial coating 180 and the defective surface layer have been removed. The etched surface 117.3 can have reduced defects relative to the original surface and can provide a pristine template for growth.

The formation of the sacrificial coating 180 can be achieved in various ways without deviating from the scope of the present disclosure. In some embodiments, the coating 180 is a layer of silicon oxide (SiO₂) formed by thermal oxidation. This is achieved by heating the seed crystal in an oxygen-containing atmosphere, causing the top layer of silicon carbide to react and form a protective SiO₂ layer. This process may consume the defective surface layer of the seed crystal 116.1. During the subsequent heat-up in the crystal growth chamber, this SiO₂ layer evaporates, exposing the pristine etched surface 117.3.

In some embodiments a silicon-oxide (SiOx) layer is applied using a room-temperature wet chemistry process. A chemical precursor, such as tetraethyl orthosilicate (TEOS), is applied to the seed crystal surface to deposit the SiOx coating 180. Similar to a thermally grown oxide, this chemically applied layer treats the seed surface and subsequently evaporates during the heat-up phase to prepare the surface for growth.

In some embodiments, the sacrificial coating 180 comprises a layer of elemental silicon or metal capable of dissolving silicon carbide. This layer can be deposited onto the seed crystal 116.1 as a powder or via a thin-film deposition technique such as e-beam evaporation or sputtering. During heat-up in the crucible, this silicon layer melts and dissolves the top surface of the seed crystal, performing a solid-liquid etchback in the reaction zone 117.2. As the excess silicon subsequently evaporates, the dissolved silicon carbide is redeposited, leaving a repaired and pristine etched surface 117.3 for bulk crystal growth

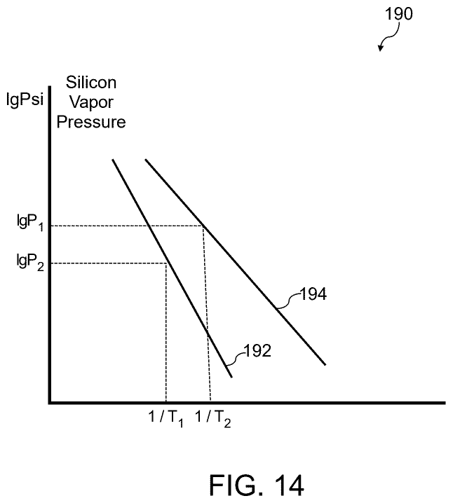

FIG. 14 illustrates an example implementation of a graph 190 showing thermodynamic relationships for an in situ etching process. The graph 190 can plot silicon vapor pressure (IgPsi) on a vertical axis versus an inverse of temperature (1/T) on a horizontal axis. The graph 190 can include a seed silicon vapor pressure curve 192 for the seed and an etching agent silicon vapor pressure curve 194 for the etching agent.

The seed silicon vapor pressure curve 192 can represent the equilibrium vapor pressure of silicon at the seed crystal surface as a function of inverse temperature. The source silicon vapor pressure curve 194 can represent the vapor pressure of silicon at a source (e.g., with etching agent such as elemental silicon) as a function of inverse temperature. T1 is the temperature of the seed and T2 is the temperature of the source.

As depicted, at first inverse temperature 1/T1, the silicon source vapor pressure can be IgP2, as shown on the seed silicon vapor pressure curve 192. At a second inverse temperature 1/T2, the equilibrium silicon vapor pressure of the seed can be IgP1, as shown on the source silicon vapor pressure curve 194. In some embodiments, to etch the seed without graphitization, T1 is greater than T2 and IgP2 at the source is greater than IgP1 at the seed. Accordingly, a temperature difference T1−T2 may be selected to satisfy the conditions T1>T2 and IgP2>IgP1. However, if the difference in silicon vapor pressure is too great, it can cause silicon to condense on the crystal.

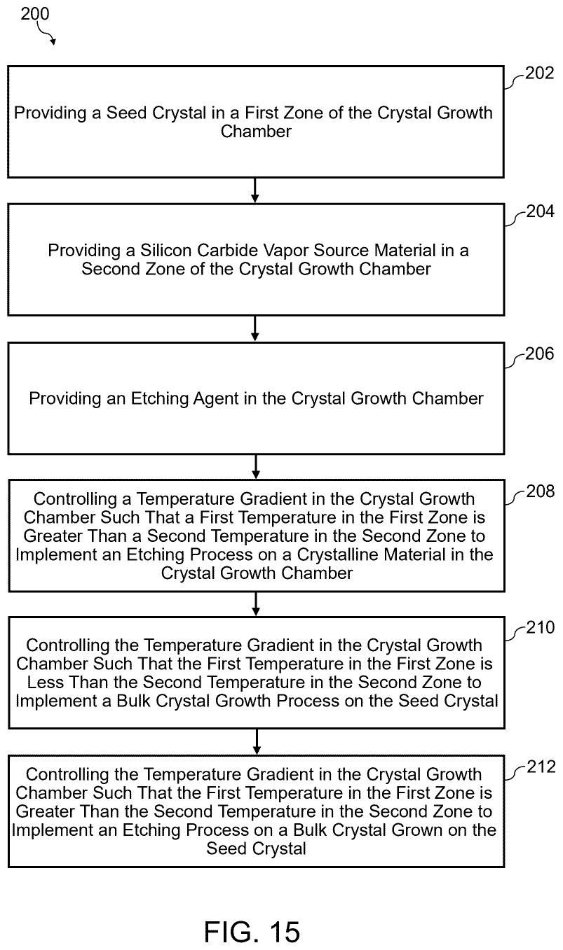

FIG. 15 illustrates a flow chart of an example method 200 according to examples of the present disclosure. The method 200 can be implemented, for instance, using any of the crystal growth systems described herein. The method 200 includes operations illustrated in a particular order for purposes of illustration and discussion. Those of ordinary skill in the art, using the disclosures provided herein, will understand that the various steps or operations of any of the methods provided herein can be rearranged, omitted, include steps not illustrated, expanded, adapted, and/or modified in various ways without deviating from the scope of the present disclosure.

The method begins with operation 202, which involves providing a seed crystal in a first zone of the crystal growth chamber. The seed crystal serves as a template upon which the bulk crystalline material will be grown, defining its crystallographic orientation.

Next, operation 204 involves providing a silicon carbide vapor source material in a second zone of the crystal growth chamber. This material, which can be a powder or a solid structure, is the substance that will sublimate to form the vapor species for the PVT process.

Operation 206 involves providing an etching agent within the crystal growth chamber. The etching agent is a substance that facilitates a surface etching process on the crystalline material and can be a silicon vapor, an introduced gas, or a metal vapor. The operation of providing an etching agent in the crystal growth chamber is intended to encompass introducing the etching agent in its final form (e.g., as a powder or gas) as well as generating the etching agent in situ within the chamber, for instance by the reaction of two or more precursor materials introduced into the chamber.

Following the setup, operation 208 provides an in situ etching operation wherein a temperature gradient is controlled such that a first temperature in the first zone is greater than a second temperature in the second zone. This inverted temperature gradient is established to implement an etching process on a crystalline material, such as the initial seed crystal, to remove a damaged or contaminated surface layer.

After etching, the method may include operation 210. Operation 210 provides a bulk crystal growth operation where the temperature gradient is inverted from the etching condition. The first temperature in the first zone is controlled to be less than the second temperature in the second zone to implement a bulk crystal growth process, driving the transport of sublimated vapor from the source material to deposit on the seed crystal to grow the bulk crystalline material.

The method may also include operation 212, which is a subsequent etching operation performed after a period of bulk crystal growth. The temperature gradient is again controlled so the first temperature is greater than the second temperature, implementing an intermediate etching process on the newly grown bulk crystal to remove any defects that may have formed on the growing surface before growth is resumed.

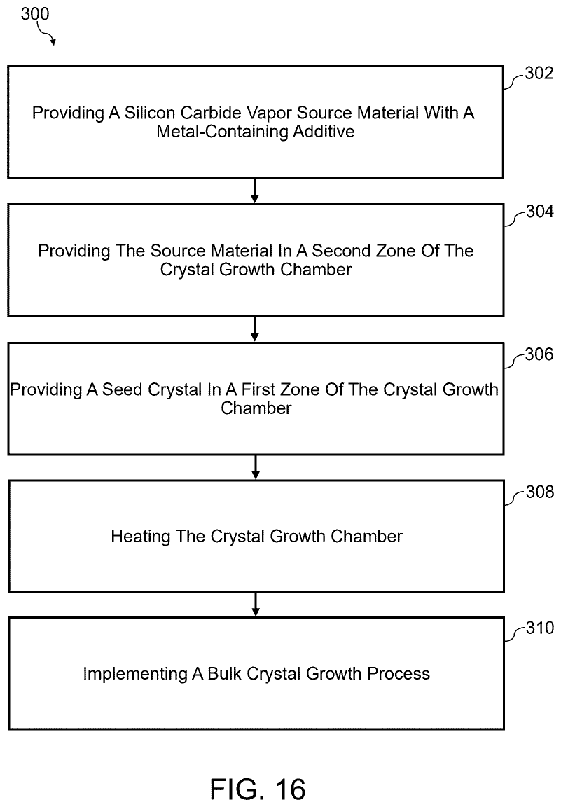

FIG. 16 illustrates a flow chart of an example method 300 for preparing a silicon carbide source material for a crystal growth process according to examples of the present disclosure. The method 300 can be implemented, for instance, using any of the crystal growth systems described herein. The method 300 includes operations illustrated in a particular order for purposes of illustration and discussion. Those of ordinary skill in the art, using the disclosures provided herein, will understand that the various steps or operations can be rearranged, omitted, or modified without deviating from the scope of the present disclosure.

The method 300 begins with operation 302, which involves providing a silicon carbide vapor source material with source conditioning agent, such as a metal-containing additive. The metal-containing additive may include, but is not limited to, calcium, strontium, barium, tin, bismuth, lead, lanthanum, cerium, praseodymium, or neodymium. In some embodiments, the metal-containing additive can be supplied in various forms, including but not limited to, a pure metal, an oxide, a silicate, a carbide, or other suitable metal compound. In embodiments where the additive is provided, for instance, as a metal oxide, it may be combined with an oxygen-getter such as elemental carbon or silicon. This combination can mitigate the premature release of oxygen at lower temperatures during the initial heat-up phase of the process.

Next, operation 304 involves providing the source material in a second zone of the crystal growth chamber. This is followed by operation 306, providing a seed crystal in a first zone of the crystal growth chamber.

At operation 308, the crystal growth chamber is heated during an initial heat-up phase. This heating is controlled to implement the source pre-conditioning process at a moderate temperature. The temperature is sufficient to vaporize the metal-containing additive, which then reacts with and removes impurities from the surface of the silicon carbide vapor source material. In some embodiments, the temperature is in a range of about 500° C. to about 2000° C., such as about 700° C. to about 1900° C., such as about 1200° C. to about 1900° C., such as about 1400° C. to about 1900° C. This operation cleans the source material in-situ, primarily by reacting with oxygen-related impurities, before they can be transported to the seed crystal.

Finally, after the source material has been cleaned, operation 310 involves implementing a bulk crystal growth process. This operation uses the cleaned silicon carbide vapor source material, which is sublimated and transported to the seed crystal to grow a high-quality bulk crystal with a reduced density of SOG defects.

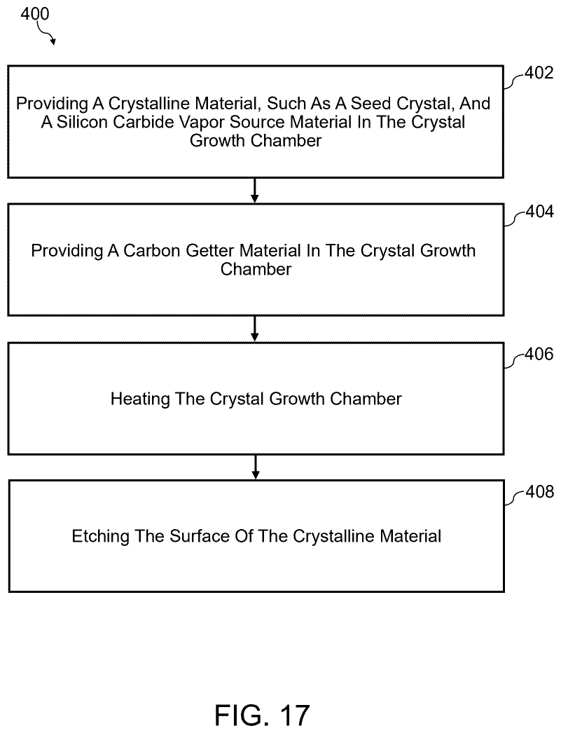

FIG. 17 illustrates a flow chart of an example method 400 for etching a crystalline material using a carbon getter according to examples of the present disclosure. The method 400 can be implemented, for instance, using a crystal growth system such as that depicted in FIG. 12. The method 400 includes operations illustrated in a particular order for purposes of illustration and discussion. Those of ordinary skill in the art, using the disclosures provided herein, will understand that the various steps or operations can be rearranged, omitted, or modified without deviating from the scope of the present disclosure.

The method 400 begins with operation 402, which involves providing a crystalline material, such as a seed crystal, and a silicon carbide vapor source material in the crystal growth chamber. Next, at operation 404, a carbon getter material is provided in the crystal growth chamber. The carbon getter, which may comprise tantalum oxide (Ta₂O₅), is positioned at a location between the crystalline material and the source material, for example on an interface structure.

At operation 406, the crystal growth chamber is heated to an operating temperature. The heating causes the carbon getter material to become chemically active and consume elemental carbon from the vapor environment within the chamber. The consumption of carbon, in turn, leads to the creation of a silicon-rich atmosphere in the vicinity of the crystalline material.

Finally, at operation 408, the silicon-rich atmosphere etches a surface of the crystalline material. This etching process occurs without establishing an inverted temperature gradient where the crystalline material is hotter than the source material, thereby providing a surface for subsequent crystal growth.

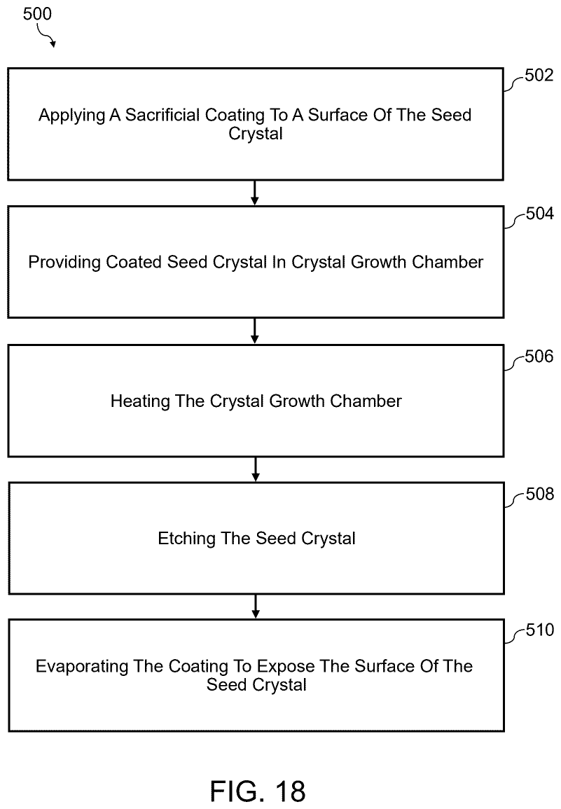

FIG. 18 illustrates a flow chart of an example method 500 for preparing a seed crystal using a sacrificial, evaporable coating, according to examples of the present disclosure. This method provides for the in-situ cleaning and preparation of a seed crystal surface prior to a growth process. The method 500 includes operations illustrated in a particular order for purposes of illustration and discussion; however, the steps can be rearranged, omitted, or modified without deviating from the scope of the present disclosure.

The method 500 begins with operation 502, which involves applying a sacrificial coating to a surface of the seed crystal. This coating can be formed through several different methods, including thermal oxidation to form a silicon oxide (SiO₂) layer, application of a silicon-oxide layer via a wet chemistry process, or deposition of a layer of elemental silicon.

Next, at operation 504, the coated seed crystal is placed into the crystal growth chamber. At operation 506, the crystal growth chamber is heated. The heating causes the coating to etch a surface layer of the seed crystal at operation 508. In embodiments using an elemental silicon coating, this operation can comprise a solid-liquid etchback where the molten silicon dissolves the top layer of the seed crystal.

Following the etching operation, operation 510 involves the subsequent evaporation of the sacrificial coating and the removed surface layer from the seed. This exposes a pristine surface of the seed crystal that is ready for growth.

It is to be understood that the various in-situ defect mitigation techniques disclosed herein can be used individually or in any combination to achieve a multi-faceted approach to improving crystal quality. For example, the in-situ conditioning of the source material using a metal-containing additive (as described in method 300) can be performed prior to a bulk growth process that also incorporates an in-situ etch using an inverted temperature gradient (as in method 200). Similarly, a seed crystal prepared with a sacrificial coating (as in method 500) can be used in a growth process that also employs a carbon getter (as in method 400) to maintain a silicon-rich environment. These combinations can provide synergistic benefits, addressing defects originating from both the source material and the seed crystal, as well as those that form during growth, leading to a robust defect reduction strategy.

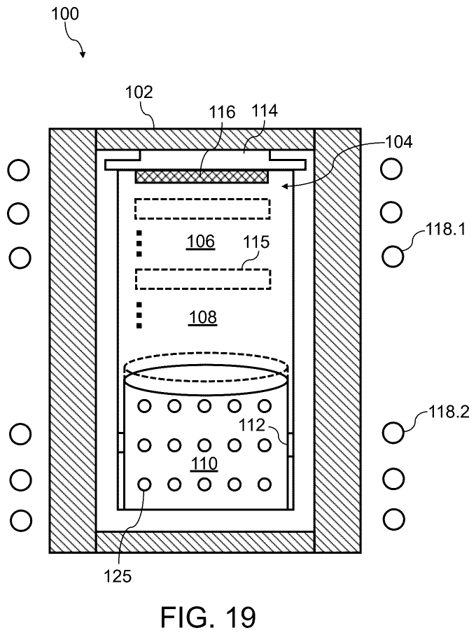

Aspects of the present disclosure may be implemented using any crystal growth system without deviating from the scope of the present disclosure. FIGS. 19-25 depict example crystal growth systems that may be used to implement the in situ etch process on a seed crystal and/or a bulk crystal material grown on the seed crystal according to examples of the present disclosure.

FIG. 19 provides a cross-sectional schematic diagram of a crystal growth system 100 adapted for use in a crystal growth process according to example embodiments of the present disclosure. The system includes a reaction crucible 102 that defines a crystal growth chamber 104. This chamber 104 may include a first zone 106 and a second zone 108. The crystal growth system 100 may include one or more heaters, such as a first heater 118.1 for the first zone 106 and a

The first zone 106 contains a seed crystal 116 supported by a seed holder 114. The second zone 108 contains a silicon carbide vapor source material 110 supported by a source material holder 112. The system may optionally include one or more interface structures 115 between the source material 110 and the seed crystal 116 to influence heat and vapor transport.

The crystal growth system 100 shown in FIG. 19 can further be configured to include an etching agent 125 within the crystal growth chamber 104. The etching agent 125 is a substance provided to facilitate an in situ surface etching process on a crystalline material, such as the seed crystal 116 or a bulk crystal grown thereon. The etching agent 125 is a substance provided to facilitate an in-situ surface etching process on a crystalline material, such as the seed crystal 116 or a bulk crystal grown thereon. The etching agent 125 can take several forms, including: a silicon vapor from a silicon vapor source used to prevent graphitization during an inverted-gradient etch; an introduced gas (such as nitrogen, hydrogen, a hydrocarbon, a sulfur-containing gas, or a silicon-containing gas) used to alter the vapor chemistry; a metal vapor (e.g., from a solid or powder source of lanthanum, cerium, praseodymium, or neodymium) deposits on the seed to preferentially remove defects; a carbon getter (such as tantalum oxide) that consumes carbon to create a silicon-rich atmosphere for etching without an inverted temperature gradient; or a sacrificial coating (such as silicon oxide or elemental silicon) applied to the seed that etches the surface before evaporating during heat-up. The etching agent 125 may be located in various positions, such as integrated with the source material 110, placed in a dedicated holder, or positioned at an interface structure 115.

To implement an in situ etching process, a controller can be used to manage a temperature gradient between the first zone 106 and the second zone 108 according to examples of the present disclosure. Specifically, the temperature gradient is controlled such that a first temperature T1 in the first zone 106 is greater than a second temperature T2 in the second zone 108. This inverted temperature gradient causes the surface of the crystalline material to be etched, thereby removing damaged or contaminated surface layers to provide a surface for subsequent crystal growth.

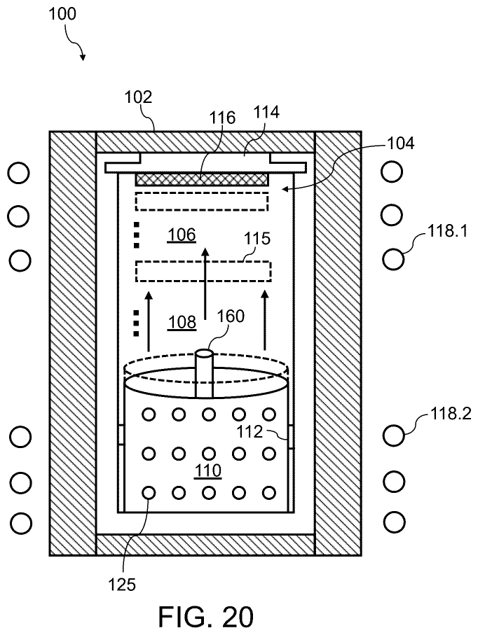

FIG. 20 provides a cross-sectional schematic diagram of a crystal growth system 100 which may include a gas inlet 160 for introducing a gas, such as a dopant (e.g., N₂) or an etching agent 125, to the reaction crucible 102. The gas inlet 160 may be, for example, a tube, pipe, or vent. As shown, the source material 110 may surround the gas inlet 160, for instance, by including a channel through which the gas inlet 160 is provided. The system 100 may optionally include one or more interface structures 115 situated within the reaction crucible 102 between the source material 110 and the seed crystal 116.

The crystal growth system 100 shown in FIG. 20 can further be configured to include an etching agent 125 within the crystal growth chamber 104. The etching agent 125 is a substance provided to facilitate an in-situ surface etching process on a crystalline material, such as the seed crystal 116 or a bulk crystal grown thereon. The etching agent 125 can take several forms, including: a silicon vapor from a silicon vapor source used to prevent graphitization during an inverted-gradient etch; an introduced gas (such as nitrogen, hydrogen, a hydrocarbon, a sulfur-containing gas, or a silicon containing gas) used to alter the vapor chemistry; a metal vapor (e.g., from a solid or powder source of lanthanum, cerium, praseodymium, or neodymium) deposits on the seed to preferentially remove defects; a carbon getter (such as tantalum oxide) that consumes carbon to create a silicon-rich atmosphere for etching without an inverted temperature gradient; or a sacrificial coating (such as silicon oxide or elemental silicon) applied to the seed that etches the surface before evaporating during heat-up. The etching agent 125 may be located in various positions, such as integrated with the source material 110, placed in a dedicated holder, positioned at an interface structure 115, or introduced as a gas through the gas inlet 160.

To implement an in situ etching process, a controller can be used to manage a temperature gradient between the first zone 106 and the second zone 108 according to examples of the present disclosure. Specifically, the temperature gradient is controlled such that a first temperature T1 in the first zone 106 is greater than a second temperature T2 in the second zone 108. This inverted temperature gradient causes the surface of the crystalline material to be etched, thereby removing damaged or contaminated surface layers to provide a surface for subsequent crystal growth.

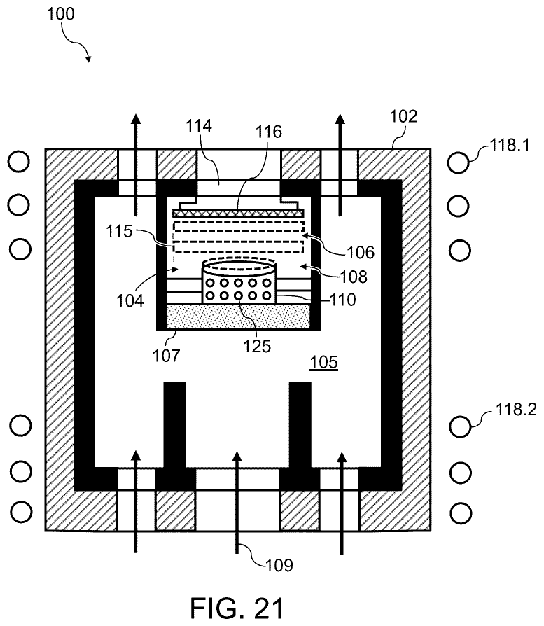

FIG. 21 shows an example embodiment where the crystal growth system 100 is a CF-PVT system. In this configuration, the reaction crucible 102 may include an upper chamber 104 and a lower chamber 105, which may be separated by a gas-permeable structure 107 such as a graphite foam. The upper chamber may contain the seed crystal 116 and the source material 110, which can be formed in-situ and continuously fed. For example, a gaseous silicon source 109 can be supplied to the lower chamber 105 and react with a source material 110 (e.g., a carbon source material) to form silicon carbide, which then serves as a high-purity source for the PVT process occurring in the upper chamber 104. The system 100 may optionally include an interface structure 115 within the upper chamber to control vapor transport and radiative heat transfer. Separate heaters, such as a first heater 118.1 and a second heater 118.2, may be used to provide independent temperature profiles to the different chambers and zones.

The crystal growth system 100 shown in FIG. 21 can further be configured to include an etching agent 125 within the crystal growth chamber 104. The etching agent 125 is a substance provided to facilitate an in-situ surface etching process on a crystalline material, such as the seed crystal 116 or a bulk crystal grown thereon. The etching agent 125 can take several forms, including: a silicon vapor from a silicon vapor source used to prevent graphitization during an inverted-gradient etch; an introduced gas (such as nitrogen, hydrogen, a hydrocarbon, a sulfur-containing gas, or a silicon-containing gas) used to alter the vapor chemistry; a metal vapor (e.g., from a solid or powder source of one or more of lanthanum, cerium, praseodymium, or neodymium) deposits on the seed to preferentially remove defects; a carbon getter (such as tantalum oxide) that consumes carbon to create a silicon-rich atmosphere for etching without an inverted temperature gradient; or a sacrificial coating (such as silicon oxide or elemental silicon) applied to the seed that etches the surface before evaporating during heat-up. The etching agent 125 may be located in various positions, such as being placed in a dedicated holder, positioned at an interface structure 115, or co-fed as a gas with the precursor gas.

To implement an in situ etching process, a controller can be used to manage a temperature gradient between the first zone 106 (containing the seed crystal 116) and the second zone 108 (containing the source material 110). Specifically, the temperature gradient is controlled such that a first temperature T1 in the first zone 106 is greater than a second temperature T2 in the second zone 108. This inverted temperature gradient causes the surface of the crystalline material to be etched, thereby removing damaged or contaminated surface layers to provide a surface for subsequent crystal growth.

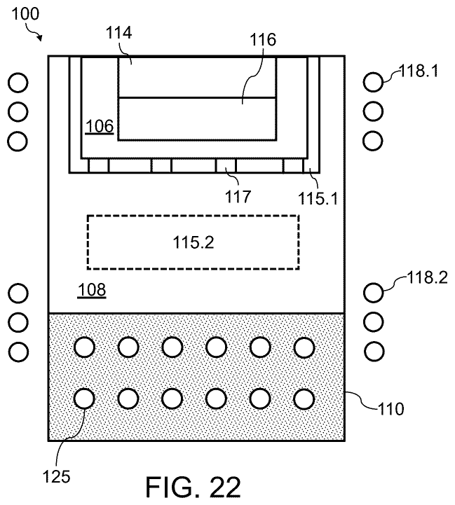

FIG. 22 depicts an example crystal growth system 100 which includes an interface structure 115.1 configured as a shell structure. In this embodiment, the interface structure 115.1 extends around at least three sides of the seed crystal 116 and may be formed from a material such as porous graphite. The interface structure 115.1 may optionally include one or more apertures 117 that assist in the transport of source vapor from the source material 110 to the seed crystal 116. The crystal growth system 100 may optionally include a second interface structure 115.2. The second interface structure 115.2 may be a baffle or other structure similar to the interface structure 115 of FIG. 2.

As shown in this example, the zones may be arranged such that the second zone 108 (containing the source material 110) is in a lower portion of the reaction crucible 102, while the first zone 106 (containing the seed crystal 116) is in an upper portion. The crystal growth system 100 may include one or more heaters, such as a first heater 118.1 for the first zone 106 and a second heater 118.2 for the second zone 108.

The crystal growth system 100 shown in FIG. 22 can further be configured to include an etching agent 125 within the crystal growth chamber 104. The etching agent 125 is a substance provided to facilitate an in-situ surface etching process on a crystalline material, such as the seed crystal 116 or a bulk crystal grown thereon. The etching agent 125 can take several forms, including: a silicon vapor from a silicon vapor source used to prevent graphitization during an inverted-gradient etch; an introduced gas (such as nitrogen, hydrogen, a hydrocarbon, a sulfur-containing gas, or a silicon-containing gas) used to alter the vapor chemistry; a metal vapor (e.g., from a solid or powder source of lanthanum, cerium, praseodymium, or neodymium) deposits on the seed to preferentially remove defects; a carbon getter (such as tantalum oxide) that consumes carbon to create a silicon-rich atmosphere for etching without an inverted temperature gradient; or a sacrificial coating (such as silicon oxide or elemental silicon) applied to the seed that etches the surface before evaporating during heat-up. The etching agent 125 may be located in various positions, such as integrated with the source material 110, placed in a dedicated holder, or positioned at an interface structure 115.1, 115.2.

To implement an in situ etching process, a controller can be used to manage a temperature gradient between the first zone 106 and the second zone 108 according to examples of the present disclosure. Specifically, the temperature gradient is controlled such that a first temperature T1 in the first zone 106 is greater than a second temperature T2 in the second zone 108. This inverted temperature gradient causes the surface of the crystalline material to be etched, thereby removing damaged or contaminated surface layers to provide a surface for subsequent crystal growth.

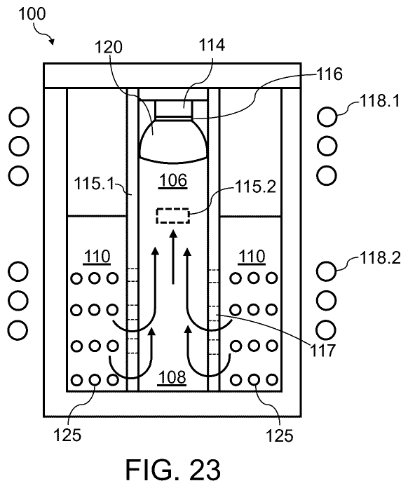

FIG. 23 shows an example crystal growth system 100 that includes a first interface structure 115.1 and an optional second interface structure 115.2. The first interface structure 115.1 may include a tubular baffle structure, and the seed crystal 116 may be positioned within this structure. The tubular structure 115.1 may be porous graphite and may optionally include one or more apertures 117. The second interface structure 115.2 may be positioned between the first interface structure 115.1 and the seed crystal 116 or bulk crystal 120 grown on the seed crystal 116. The second interface structure 115.2 may be a baffle or other structure similar to the interface structure 115 of FIG. 2.

Similar to the embodiment of FIG. 22, the zones may be arranged such that the second zone 108 is in a lower portion of the reaction crucible 102, while the first zone 106 (containing the seed crystal 116 and/or bulk crystal 120) is in an upper portion. The crystal growth system 100 may include one or more heaters, such as a first heater 118.1 for the first zone 106 and a second heater 118.2 for the second zone 108.

The crystal growth system 100 shown in FIG. 23 can further be configured to include an etching agent 125 within the crystal growth chamber 104. The etching agent 125 is a substance provided to facilitate an in-situ surface etching process on a crystalline material, such as the seed crystal 116 or a bulk crystal grown thereon. The etching agent 125 can take several forms, including: a silicon vapor from a silicon vapor source used to prevent graphitization during an inverted-gradient etch; an introduced gas (such as nitrogen, hydrogen, a hydrocarbon, a sulfur-containing gas, or a silicon-containing gas) used to alter the vapor chemistry; a metal vapor (e.g., from a solid or powder source of lanthanum, cerium, praseodymium, or neodymium) deposits on the seed to preferentially remove defects; a carbon getter (such as tantalum oxide) that consumes carbon to create a silicon-rich atmosphere for etching without an inverted temperature gradient; or a sacrificial coating (such as silicon oxide or elemental silicon) applied to the seed that etches the surface before evaporating during heat-up. The etching agent 125 may be located in various positions, such as integrated with the source material 110, placed in a dedicated holder. The etching agent 125 may be located in various positions, such as integrated with the source material 110, placed in a dedicated holder, or positioned at the first interface structure 115.1 or the second interface structure 115.2.

To implement an in situ etching process, a controller can be used to manage a temperature gradient between the first zone 106 and the second zone 108 according to examples of the present disclosure. Specifically, the temperature gradient is controlled such that a first temperature T1 in the first zone 106 is greater than a second temperature T2 in the second zone 108. This inverted temperature gradient causes the surface of the crystalline material to be etched, thereby removing damaged or contaminated surface layers to provide a surface for subsequent crystal growth.

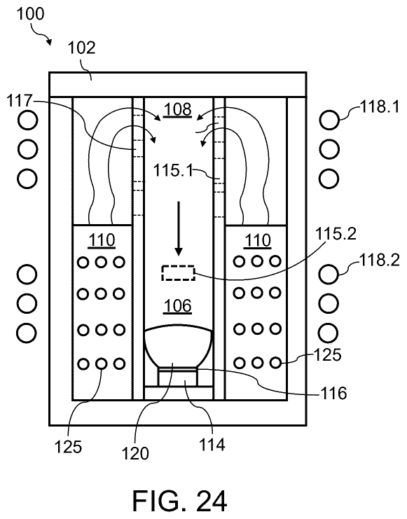

FIG. 24 depicts an example crystal growth system 100 similar to the crystal growth system of FIG. 23 with a configuration where the seed crystal 116 and/or bulk crystal 120 is positioned in a lower portion of the reaction crucible 102. During a growth process, vapor flows downwards towards the seed crystal, as indicated by the arrows. This arrangement defines the first zone 106, having a first temperature T1, in the lower portion of the crucible and the second zone 108, having a second temperature T2, in the upper portion.

The crystal growth system 100 shown in FIG. 24 can further be configured to include an etching agent 125 within the crystal growth chamber 104. The etching agent 125 is a substance provided to facilitate an in-situ surface etching process on a crystalline material, such as the seed crystal 116 or a bulk crystal grown thereon. The etching agent 125 can take several forms, including: a silicon vapor from a silicon vapor source used to prevent graphitization during an inverted-gradient etch; an introduced gas (such as nitrogen, hydrogen, a hydrocarbon, a sulfur-containing gas, or a silicon-containing gas) used to alter the vapor chemistry; a metal vapor (e.g., from a solid or powder source of lanthanum, cerium, praseodymium, or neodymium) deposits on the seed to preferentially remove defects; a carbon getter (such as tantalum oxide) that consumes carbon to create a silicon-rich atmosphere for etching without an inverted temperature gradient; or a sacrificial coating (such as silicon oxide or elemental silicon) applied to the seed that etches the surface before evaporating during heat-up. The etching agent 125 may be located in various positions, such as integrated with the source material 110 or placed in a dedicated holder. The etching agent 125 may be located in various positions, such as integrated with the source material 110 or placed in a dedicated holder.

To implement an in situ etching process in this configuration, a controller can be used to manage a temperature gradient between the first zone 106 and the second zone 108. Specifically, the temperature gradient is controlled such that the first temperature T1 in the first zone 106 at the bottom of the crucible is greater than the second temperature T2 in the second zone 108 at the top of the crucible. This inverted temperature gradient causes the surface of the crystalline material to be etched, thereby removing damaged or contaminated surface layers to provide a surface for subsequent crystal growth.

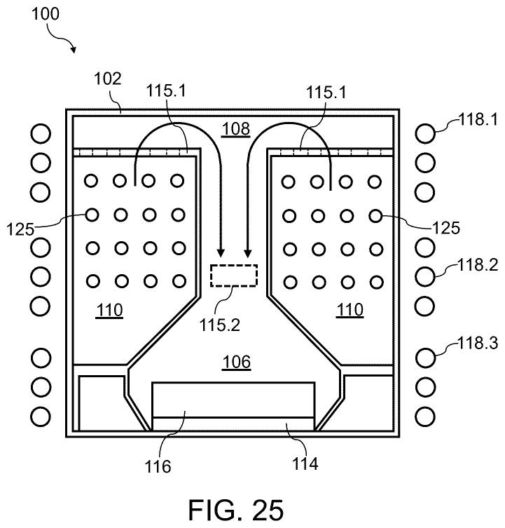

FIG. 25 shows an example crystal growth system 100 with an inverted growth configuration. In this embodiment, the seed crystal 116 is located in a lower portion of the crucible 102. During a growth process, vapor flows downwards toward the seed crystal 116, as indicated by the arrows. This arrangement defines the first zone 106, having a first temperature T1, in the lower portion of the crucible and the second zone 108, having a second temperature T2, in the upper portion.

The crystal growth system 100 of FIG. 25 may include a first interface structure 115.1 and an optional second interface structure 115.2. The first interface structure 115.1 may be a porous graphite structure with one or more apertures positioned above the silicon carbide vapor source material 110. The optional second interface structure 115.2 may be positioned between an upper portion of the crucible 102 and the seed crystal 116. The crystal growth system 100 can include one or more heaters, such as a first heater 118.1, a second heater 118.2, and/or a third heater 118.3.

The crystal growth system 100 shown in FIG. 25 can further be configured to include an etching agent 125 within the crystal growth chamber 104. The etching agent 125 is a substance provided to facilitate an in-situ surface etching process on a crystalline material, such as the seed crystal 116 or a bulk crystal grown thereon. The etching agent 125 can take several forms, including: a silicon vapor from a silicon vapor source used to prevent graphitization during an inverted-gradient etch; an introduced gas (such as nitrogen, hydrogen, a hydrocarbon, a sulfur-containing gas, or a silicon-containing gas) used to alter the vapor chemistry; a metal vapor (e.g., from a solid or powder source of lanthanum, cerium, praseodymium, or neodymium) deposits on the seed to preferentially remove defects; a carbon getter (such as tantalum oxide) that consumes carbon to create a silicon-rich atmosphere for etching without an inverted temperature gradient; or a sacrificial coating (such as silicon oxide or elemental silicon) applied to the seed that etches the surface before evaporating during heat-up. The etching agent 125 may be located in various positions, such as integrated with the source material 110 or placed in a dedicated holder.

To implement an in situ etching process in this configuration, a controller can be used to manage a temperature gradient between the first zone 106 and the second zone 108. Specifically, the temperature gradient is controlled such that the first temperature T1 in the first zone 106 (at the bottom) is greater than the second temperature T2 in the second zone 108 (at the top). This inverted temperature gradient causes the surface of the crystalline material to be etched, thereby removing damaged or contaminated surface layers to provide a surface for subsequent crystal growth.

For any of the crystal growth systems provided herein, one or more parts of the crystal growth system or the source material may be 3D printed, such as disclosed in U.S. application Ser. No. 18/963,082, which is incorporated herein by reference. For instance, in some embodiments, the 3D printed source may include a silicon carbide powder and a binder (e.g., UV curable polymer adhesive). In some embodiments, the 3D printed part may include a ceramic material (e.g., silicon carbide, metal mixed with carbon, etc.) and a binder (e.g., UV curable polymer adhesive).

In an aspect, the present disclosure provides an example method. In some implementations, the example method includes providing a crystalline material in a first zone of the crystal growth chamber. In some implementations, the example method includes providing a silicon carbide vapor source material in a second zone of the crystal growth chamber. In some implementations, the example method includes providing an etching agent in the crystal growth chamber. In some implementations, the example method includes controlling a temperature gradient in the crystal growth chamber such that a first temperature in the first zone is greater than a second temperature in the second zone to implement an etching process on the crystalline material in the crystal growth chamber.

In some implementations of the example method, the crystalline material includes a seed crystal.

In some implementations of the example method, the crystalline material includes a bulk crystalline material grown on a seed crystal.

In some implementations of the example method, the etching agent includes a silicon vapor from a silicon vapor source.

In some implementations of the example method, a first silicon vapor pressure of the silicon vapor source is greater than a second silicon vapor pressure at a surface of the crystalline material

In some implementations of the example method, the silicon vapor source includes solid silicon.

In some implementations of the example method, the silicon vapor source includes Si₃N₄.

In some implementations of the example method, the silicon vapor source includes silicon powder.

In some implementations of the example method, the silicon carbide vapor source includes silicon to provide a silicon and silicon carbide composite structure, wherein the etching agent includes the silicon in the silicon carbide and silicon composite structure.

In some implementations of the example method, the etching agent is provided in an etching agent holder separated from the source material.

In some implementations of the example method, after controlling the temperature gradient in the crystal growth chamber to implement the etching process, the method includes controlling the temperature gradient in the crystal growth chamber such that the first temperature in the first zone is less than the second temperature in the second zone to implement a bulk crystal growth process on a seed crystal.

In some implementations of the example method, after controlling the temperature gradient in the crystal growth chamber to implement the etching process, the method includes controlling the temperature gradient in the crystal growth chamber such that the first temperature in the first zone is greater than the second temperature in the second zone to implement a second etching process on a bulk crystal grown on the seed crystal.

In some implementations of the example method, controlling the temperature gradient in the crystal growth chamber includes controlling a first heater for the first zone and controlling a second heater for the second zone.

In some implementations of the example method, the etching process removes about 10 microns to about 100 microns from the crystalline material.

In some implementations of the example method, the crystal growth chamber includes an interface structure between the first zone and the second zone.

In some implementations of the example method, providing the etching agent includes providing the etching agent at the interface structure between the first zone and the second zone.

In some implementations of the example method, controlling the temperature gradient includes controlling a temperature difference between the first temperature and the second temperature to control an etch rate of the etching process on the crystalline material.

In some implementations of the example method, a difference between the first temperature and the second temperature is in a range of about 30 degrees Celsius and about 100 degrees Celsius.

In some implementations of the example method, the etching agent is introduced into the crystal growth chamber as a gas.

In some implementations of the example method, the gas includes one or more of nitrogen, hydrogen, carbon monoxide, a hydrocarbon, a sulfur-containing gas, or a silicon-containing gas.

In some implementations of the example method, the etching process includes thermally graphitizing a surface of the crystalline material to form a graphitic surface. In some implementations of the example method, the etching process includes etching the graphitic surface using the gas.

In some implementations of the example method, the gas is introduced to alter an equilibrium Si:C ratio in a vapor within the crystal growth chamber to control the etching process.

In some implementations of the example method, the gas is injected directly into an interior of a reaction crucible containing the crystalline material to prevent pre-reaction of the gas before it reaches the crystalline material.

In some implementations of the example method, the etching agent includes a carbon getter.

In some implementations of the example method, the etching agent includes a metal vapor.

In some implementations of the example method, the metal vapor is provided from a metal vapor source, the metal vapor source including one or more of lanthanum, cerium, praseodymium, or neodymium.

In some implementations of the example method, the metal vapor deposits on a surface of the crystalline material to perform the etching.

In some implementations of the example method, the etching preferentially removes defective regions selected from the group consisting of dislocations, stacking faults, and micropipes.

In some implementations of the example method, the metal vapor includes a non-incorporating etchant that does not alter an electrical property of the crystalline material.

In some implementations of the example method, the etching agent includes a sacrificial coating on the crystalline material.

In some implementations of the example method, the sacrificial coating includes SiOx.

In some implementations of the example method, the sacrificial coating includes silicon.

In an aspect, the present disclosure provides an example method. In some implementations, the example method includes providing a crystalline material in a first zone of the crystal growth chamber. In some implementations, the example method includes providing a silicon carbide vapor source material in a second zone of the crystal growth chamber, the second zone separated from the first zone by an interface structure. In some implementations, the example method includes controlling a temperature gradient in the crystal growth chamber such that a first temperature in the first zone is greater than a second temperature in the second zone to implement an etching process on the crystalline material in the crystal growth chamber.

In some implementations of the example method, the method further includes providing an etching agent in the crystal growth chamber at the interface structure.

In some implementations of the example method, the etching agent includes a silicon vapor source.

In some implementations of the example method, the etching agent includes a metal vapor from a metal vapor source, the metal vapor source including one or more of lanthanum, cerium, praseodymium, or neodymium.

In some implementations of the example method, after controlling the temperature gradient to implement the etching process, the method includes controlling the temperature gradient such that the first temperature is less than the second temperature to implement a bulk crystal growth process on the crystalline material.

In some implementations of the example method, the crystalline material is a seed crystal.

In some implementations of the example method, the crystalline material is a bulk crystal grown on a seed crystal.

In an aspect, the present disclosure provides an example method. In some implementations, the example method includes providing a source material in the crystal growth chamber, the source material including a silicon carbide vapor source material and a metal-containing additive. In some implementations, the example method includes heating the source material such that the metal-containing additive vaporizes and reacts with impurities on a surface of the silicon carbide vapor source material.

In some implementations of the example method, the impurities include oxygen-containing impurities.

In some implementations of the example method, the metal-containing additive includes one or more of calcium, strontium, barium, tin, bismuth, lead, lanthanum, cerium, praseodymium, or neodymium.

In some implementations of the example method, the metal-containing additive is provided in a form including one or more of a reduced metal, a metal oxide, and a metal carbonate.

In some implementations of the example method, heating the source material occurs at a temperature sufficient to vaporize the metal-containing additive but below a sublimation temperature for sublimation of the silicon carbide vapor source material.

In some implementations of the example method, heating the source material occurs at a temperature in a range of about 500° C. to about 2000° C.

In some implementations of the example method, the method includes, after heating the source material, controlling a temperature gradient in the crystal growth chamber such that a first temperature in a first zone including a seed crystal is greater than a second temperature in a second zone containing the silicon carbide vapor source material to implement an etching process on the seed crystal.

In an aspect, the present disclosure provides an example method. In some implementations, the example method includes providing a crystalline material and a source material in the crystal growth chamber. In some implementations, the example method includes providing a carbon getter material in the crystal growth chamber at a location between the crystalline material and the source material. In some implementations, the example method includes heating the crystal growth chamber to a temperature sufficient to cause the carbon getter material to consume elemental carbon from an environment of the chamber, thereby creating a silicon-rich vapor that etches a surface of the crystalline material.

In some implementations of the example method, the etching of the surface of the crystalline material occurs without establishing an inverted temperature gradient where the crystalline material is hotter than the source material.

In some implementations of the example method, the carbon getter material includes tantalum oxide.

In some implementations of the example method, the crystalline material is a seed crystal or a bulk crystal grown on a seed crystal.

In some implementations of the example method, the carbon getter material is provided on an interface structure positioned between the crystalline material and the source material.

In an aspect, the present disclosure provides an example method. In some implementations, the example method includes applying a sacrificial coating to a surface of the seed crystal. In some implementations, the example method includes placing the seed crystal with the sacrificial coating into a crystal growth chamber. In some implementations, the example method includes heating the crystal growth chamber to cause the sacrificial coating to etch a surface layer of the seed crystal.

In some implementations of the example method, heating the crystal growth chamber includes heating the crystal growth chamber to cause the sacrificial coating to evaporate to expose the surface of the seed crystal.

In some implementations of the example method, applying the sacrificial coating includes thermally oxidizing the surface of the seed crystal to form a silicon oxide layer.

In some implementations of the example method, applying the sacrificial coating includes applying a silicon-oxide layer via a wet chemistry process.

In some implementations of the example method, the wet chemistry process utilizes tetraethyl orthosilicate (TEOS).

In some implementations of the example method, the sacrificial coating includes a layer of elemental silicon.

In some implementations of the example method, heating the crystal growth chamber causes the layer of elemental silicon to melt and perform a solid-liquid etchback on the surface of the seed crystal.

In an aspect, the present disclosure provides an example crystal growth system. In some implementations, the example crystal growth system includes a crystal growth chamber including a first zone and a second zone. In some implementations, the example crystal growth system includes a crystalline material in the first zone. In some implementations, the example crystal growth system includes an etching agent in the crystal growth chamber. In some implementations, the example crystal growth system includes a controller configured to control a temperature gradient between the first zone and the second zone such that a first temperature of the first zone is greater than a second temperature of the second zone to implement an etching process on the crystalline material.

In some implementations of the example crystal growth system, the controller is further configured to control the temperature gradient such that the first temperature is less than the second temperature to implement a bulk crystal growth process on a seed crystal.

In some implementations of the example crystal growth system, the etching agent includes a silicon vapor source.

In some implementations of the example crystal growth system, the etching agent is a gas supplied to the crystal growth chamber.

In some implementations of the example crystal growth system, the gas includes one or more of nitrogen, hydrogen, carbon monoxide, a hydrocarbon, a sulfur-containing gas, or a silicon-containing gas.

In some implementations of the example crystal growth system, the etching agent includes a metal vapor from a metal vapor source, the metal vapor source including one or more of lanthanum, cerium, praseodymium, or neodymium.

In some implementations of the example crystal growth system, the etching agent includes a carbon getter.

In some implementations of the example crystal growth system, the carbon getter includes tantalum oxide.

In an aspect, the present disclosure provides an example crystal growth system. In some implementations, the example crystal growth system includes a crystal growth chamber including a first zone and a second zone. In some implementations, the example crystal growth system includes a crystalline material in the first zone. In some implementations, the example crystal growth system includes a silicon carbide vapor source material in the second zone. In some implementations, the example crystal growth system includes an etching agent holder separated from the silicon carbide vapor source material operable to hold an etching agent material in the crystal growth chamber.

In some implementations of the example crystal growth system, the etching agent material includes elemental silicon.

In some implementations of the example crystal growth system, the elemental silicon is a powder.

In some implementations of the example crystal growth system, the etching agent material includes Si₃N₄.

In some implementations of the example crystal growth system, the etching agent material includes one or more of lanthanum, cerium, praseodymium, or neodymium.

In some implementations of the example crystal growth system, the system further includes a controller configured to control a temperature gradient between the first zone and the second zone.

In an aspect, the present disclosure provides an example crystal growth system. In some implementations, the example crystal growth system includes a crystal growth chamber including a first zone and a second zone. In some implementations, the example crystal growth system includes a crystalline material in the first zone. In some implementations, the example crystal growth system includes a silicon carbide vapor source material in the second zone. In some implementations, the silicon carbide vapor source includes a composite material, wherein the composite material includes an etching agent for etching the crystalline material in the crystal growth chamber.

In some implementations of the example crystal growth system, the etching agent includes silicon.

In some implementations of the example crystal growth system, the etching agent includes one or more of lanthanum, cerium, praseodymium, or neodymium.

In some implementations of the example crystal growth system, the system further includes a controller configured to control a temperature gradient between the first zone and the second zone such that a first temperature of the first zone is greater than a second temperature of the second zone to implement an etching process on the crystalline material.

In some implementations of the example crystal growth system, the controller is further configured to control the temperature gradient such that the first temperature is less than the second temperature to implement a bulk crystal growth process on the crystalline material.

In some implementations of the example crystal growth system, the crystalline material is a seed crystal.

In some implementations of the example crystal growth system, the crystalline material is a bulk crystal grown on a seed crystal.

In an aspect, the present disclosure provides a crystal growth system. The crystal growth system includes a crystal growth chamber; a seed crystal in a first zone of the crystal growth chamber; a source material in a second zone of the growth chamber; and a carbon getter material positioned between the source material and the seed crystal.

In some implementations of the example crystal growth system, the system includes an interface structure positioned between the first zone and the second zone, wherein the carbon getter material is located on the interface structure.

In some implementations of the example crystal growth system, the carbon getter material includes tantalum oxide.

In some implementations of the example crystal growth system, the system includes a controller configured to operate at least one heater to etch the surface of the seed crystal when the second zone is hotter than the first zone.

In an aspect, the present disclosure provides an example method. In some implementations, the example method includes providing a crystalline material and a source material within a semi-permeable crystal growth chamber. In some implementations, the example method includes establishing a forward temperature gradient in the crystal growth chamber such that the source material is at a higher temperature than the crystalline material, defining a source flux of vapor from the source material to the crystalline material. In some implementations, the example method includes introducing an inert gas into the crystal growth chamber at a pressure sufficient to impede the source flux, such that an outward leak flux of material from the crystalline material through the semi-permeable crystal growth chamber is greater than the source flux, thereby causing a net removal of material from a surface of the crystalline material.

In some implementations of the example method, the crystalline material includes a silicon carbide seed crystal.

In some implementations of the example method, the semi-permeable crystal growth chamber includes a crucible having inherent porosity or leaks.

In some implementations of the example method, the crucible includes porous graphite.

In some implementations of the example method, one or more etch products removed from the surface of the crystalline material are dispersed away from the crystalline material through pores in the semi-permeable crystal growth chamber.

In some implementations of the example method, the method further includes providing an etching agent in the semi-permeable crystal growth chamber.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A method of growing silicon carbide crystalline material using a physical vapor transport process in a crystal growth chamber, the method comprising:
providing a crystalline material in a first zone of the crystal growth chamber;
providing a silicon carbide vapor source material in a second zone of the crystal growth chamber;
providing an etching agent in the crystal growth chamber;
controlling a temperature gradient in the crystal growth chamber such that a first temperature in the first zone is greater than a second temperature in the second zone to implement an etching process on the crystalline material in the crystal growth chamber.

2. The method of claim 1, wherein the crystalline material comprises a seed crystal.

3. The method of claim 1, wherein the crystalline material comprises a bulk crystalline material grown on a seed crystal.

4. The method of claim 1, wherein the etching agent comprises a silicon vapor from a silicon vapor source.

5. The method of claim 4, wherein a first silicon vapor pressure of the silicon vapor source is greater than a second silicon vapor pressure at a surface of the crystalline material.

6. The method of claim 1, wherein after controlling the temperature gradient in the crystal growth chamber to implement the etching process, the method comprises controlling the temperature gradient in the crystal growth chamber such that the first temperature in the first zone is less than the second temperature in the second zone to implement a bulk crystal growth process on a seed crystal.

7. The method of claim 6, wherein after controlling the temperature gradient in the crystal growth chamber to implement the etching process, the method comprises controlling the temperature gradient in the crystal growth chamber such that the first temperature in the first zone is greater than the second temperature in the second zone to implement a second etching process on a bulk crystal grown on the seed crystal.

8. The method of claim 1, wherein the crystal growth chamber comprises an interface structure between the first zone and the second zone.

9. The method of claim 1, wherein the etching agent is introduced into the crystal growth chamber as a gas.

10. The method of claim 9, wherein the gas comprises one or more of nitrogen, hydrogen, carbon monoxide, a hydrocarbon, a sulfur-containing gas, or a silicon-containing gas.

11. The method of claim 1, wherein the etching agent comprises a metal vapor.

12. The method of claim 11, wherein the metal vapor is provided from a metal vapor source, the metal vapor source comprising one or more of lanthanum, cerium, praseodymium, or neodymium.

13. The method of claim 1, wherein the etching agent comprises a carbon getter.

14. The method of claim 1, wherein the etching agent comprises a sacrificial coating on the crystalline material.

15. A method of preparing a silicon carbide source material for a physical vapor transport process in a crystal growth chamber, the method comprising:
providing a source material in the crystal growth chamber, the source material comprising a silicon carbide vapor source material and a metal-containing additive; and
heating the source material such that the metal-containing additive vaporizes and reacts with impurities on a surface of the silicon carbide vapor source material.

16. The method of claim 15, wherein the metal-containing additive comprises one or more of calcium, strontium, barium, tin, bismuth, lead, lanthanum, cerium, praseodymium, or neodymium.

17. The method of claim 15, wherein heating the source material occurs at a temperature sufficient to vaporize the metal-containing additive but below a temperature for sublimation of the silicon carbide vapor source material.

18. A method of preparing a seed crystal for a crystal growth process, the method comprising:
applying a sacrificial coating to a surface of the seed crystal;
placing the seed crystal with the sacrificial coating into a crystal growth chamber; and
heating the crystal growth chamber to cause the sacrificial coating to etch a surface layer of the seed crystal.

19. The method of claim 18, wherein applying the sacrificial coating comprises thermally oxidizing the surface of the seed crystal to form a silicon oxide layer.

20. The method of claim 18, wherein the sacrificial coating comprises a layer of elemental silicon.
